(19) United States
(12) Patent Application Publication
(10) Pub. No.: US 2025/0088163 A1
(43) Pub. Date: Mar. 13, 2025

(54) FILTER AND MANUFACTURING METHOD THEREFOR, AND ELECTRONIC DEVICE

(71) Applicants: Beijing BOE Optoelectronics Technology Co., Ltd., Beijing (CN); BOE TECHNOLOGY GROUP CO., LTD., Beijing (CN)

(72) Inventors: Hao YAN, Beijing (CN); Qichang AN, Beijing (CN); Yue LI, Beijing (CN); Chuncheng CHE, Beijing (CN)

(73) Assignees: Beijing BOE Optoelectronics Technology Co., Ltd., Beijing (CN); BOE TECHNOLOGY GROUP CO., LTD., Beijing (CN)

(21) Appl. No.: 18/580,143

(22) PCT Filed: May 25, 2022
(86) PCT No.: PCT/CN2022/094988

§ 371 Date: Jan. 17, 2024

(51) Int. Cl. H03H 1/00; H03H 3/00; H03H 7/01

(52) U.S. Cl. CPC H03H 1/00; H03H 3/00; H03H 7/0115

(57) ABSTRACT

A filter includes an inductor and a capacitor. A first electrode of the capacitor is connected to a first terminal of the inductor. The filter further includes: a base substrate, having at least one functional hole; at least one heat dissipation column, arranged corresponding to the at least one functional hole, where the heat dissipation column is filled in the functional hole corresponding thereto; and a first conductive layer, located on a side of the base substrate. The first conductive layer includes a first conductive line, a first transfer line, and a second conductive layer. The second conductive layer includes a second conductive line and a third conductive line.

### CROSS REFERENCE TO RELATED APPLICATION(S)

The present disclosure is a 35 U.S.C. 371 national phase application of PCT International Application No. PCT/CN2022/094988 filed on May 25, 2022, the entire content of which is incorporated herein by reference.

### TECHNICAL FIELD

The present disclosure relates to the field of electronic technology, and specifically to a filter, a manufacturing method thereof, and an electronic device.

### BACKGROUND

As the size of a device continues to shrink and the integration level becomes higher and higher, the power consumption of the device may increase significantly, but the heat dissipation cannot be effectively reduced due to the increase in integration level. If the heat cannot be effectively and quickly dissipated out from the device, it will directly cause the device to fail due to high temperature, thus seriously affecting the performance and reliability of the device.

It should be noted that the information disclosed in the background section is only used to enhance understanding of the background of the present disclosure, and therefore may include information that does not constitute prior art known to those of ordinary skill in the art.

### SUMMARY

The purpose of the present disclosure is to overcome the above-mentioned shortcomings of the relevant art and provide a filter, a manufacturing method thereof, and an electronic device.

According to an aspect of the present disclosure, a filter is provided, including an inductor and a capacitor. A first electrode of the capacitor is connected to a first terminal of the inductor. The filter further includes: a base substrate, having at least one functional hole; at least one heat dissipation column, being arranged corresponding to the functional hole, where the heat dissipation column is filled in the corresponding functional hole; a first conductive layer, located on a side of the base substrate; and a second conductive layer, located on a side of the first conductive layer away from the base substrate. The first conductive layer includes: a first conductive line, a partial structure of the first conductive line being used to form the first electrode of the capacitor; a first transfer line, connected to a side of the first conductive line. The second conductive layer includes: a second conductive line, arranged corresponding to the first conductive line, where the orthographic projection of the second conductive line on the base substrate is located on the orthographic projection of the first conductive line on the base substrate, and the second conductive line is used to form a second electrode of the capacitor; and a third conductive line, located on a side of the second conductive line and arranged corresponding to the first transfer line, where the third conductive line is connected to the first transfer line through a via hole, and the third conductive line is used to form a partial coil structure of the inductor. At least some of the at least one heat dissipation column is insulated from the first conductive layer. The thermal conductivity of the heat dissipation column is greater than the thermal conductivity of the base substrate.

In an exemplary embodiment of the present disclosure, the opening areas of the functional hole at various positions are the same; or, the opening area of the functional hole gradually decreases from one side of the base substrate to the other side of the base substrate, or, the opening area of the functional hole gradually decreases from both sides of the base substrate to a middle position.

In an exemplary embodiment of the present disclosure, a ratio of a length of the functional hole in the thickness direction of the base substrate to an aperture of the functional hole is greater than or equal to 5 and less than or equal to 7.

In an exemplary embodiment of the present disclosure, the heat dissipation column is a hollow heat dissipation column, and the extension direction of the cavity of the heat dissipation column is the same as the extension direction of the heat dissipation column.

In an exemplary embodiment of the present disclosure, the heat dissipation column is a solid heat dissipation column.

In an exemplary embodiment of the present disclosure, the heat dissipation column is a conductive column.

In an exemplary embodiment of the present disclosure, the filter further includes: a first dielectric layer, located between the first conductive layer and the second conductive layer, where the first dielectric layer is arranged corresponding to the second conductive layer, and the orthographic projection of the first dielectric layer on the base substrate covers the orthographic projection of the second conductive line on the base substrate; and a first seed layer, located between the first dielectric layer and the second conductive layer, where the first seed layer is used as a seed layer for forming the second conductive layer.

In an exemplary embodiment of the present disclosure, the filter further includes a third conductive layer, located on a side of the second conductive layer away from the base substrate. The third conductive layer includes a fourth conductive line. The fourth conductive line is arranged corresponding to the third conductive line. The fourth conductive line is used to form a partial coil structure of the inductor. The third conductive line and the fourth conductive line are arranged in a bending way. The orthographic projection of the third conductive line on the base substrate and the orthographic projection of the fourth conductive line on the base substrate enclose a winding area. The first end of the third conductive line is connected to the first end of the fourth conductive line through a via hole. The second end of the third conductive line is connected to the first transfer line through a via hole. The extension direction from the first end to the second end of the third conductive line is the same as the extension direction from the first end to the second end of the fourth conductive line. In an exemplary embodiment of the present disclosure, the thickness of the second conductive layer and the thickness of the third conductive layer are both greater than the thickness of the first conductive layer.

In an exemplary embodiment of the present disclosure, the ratio of the thickness of the second conductive layer to the thickness of the first conductive layer, and the ratio of the thickness of the third conductive layer to the thickness of the first conductive layer are greater than or equal to 1.5 and less than or equal to 3.

In an exemplary embodiment of the present disclosure, the second conductive layer further includes a first connection part, located between the second conductive line and the third conductive line, and arranged corresponding to the first conductive line. The first connection part is connected to the first conductive line through a via hole. The third conductive layer further includes a second connection part and a third connection part. The second connection part is arranged corresponding to the second conductive line. The orthographic projection of the second connection part on the base substrate at least partially overlaps with the orthographic projection of the second conductive line on the base substrate. The second connection part is connected to the second conductive line through a via hole. The third connection part is arranged corresponding to the first connection part. The orthographic projection of the third connection part on the base substrate at least partially overlaps with the orthographic projection of the first connection part on the base substrate. The third connection part is connected to the first connection part through a via hole. The filter further includes a solder ball layer, located on a side of the third conductive layer away from the base substrate. The solder ball layer includes: a first solder ball, the orthographic projection of the first solder ball on the base substrate overlapping with the orthographic projection of the fourth conductive line on the base substrate, and the first solder ball being connected to an end of the fourth conductive line through a via hole; a second solder ball, the orthographic projection of the second solder ball on the base substrate overlapping with the orthographic projection of the third connection part on the base substrate, and the second solder ball being connected to the third connection part through a via hole; and a third solder ball, the orthographic projection of the third solder ball on the base substrate overlapping with the orthographic projection of the second connection part on the base substrate, and the third solder ball being connected to the second connection part through a via hole.

In an exemplary embodiment of the present disclosure, the functional hole is a blind hole, and the opening of the blind hole is located on a side of the base substrate away from the first conductive layer.

In an exemplary embodiment of the present disclosure, the functional hole is a through hole, or the functional hole is a blind hole and the opening of the blind hole is located on a side of the base substrate close to the first conductive layer. The filter further includes a first insulation layer. The first insulation layer covers the base substrate on a side facing the first conductive layer.

In an exemplary embodiment of the present disclosure, the base substrate includes a first functional area and a second functional area. The orthographic projection of the first transfer line on the base substrate is located in the first functional area. The orthographic projection of the first conductive line on the base substrate is located in the second functional area. Both the first functional area and the second functional area include the functional hole. The functional hole in the first functional area is a through hole. The plurality of heat dissipation columns located in the first functional area include a plurality of first conductive columns and a plurality of second conductive columns. The plurality of first conductive columns and the plurality of second conductive columns are arranged at intervals along the same direction respectively. The first conductive column and the second conductive column are arranged side by side. The first conductive column and the second conductive column are used to form partial coil structures of the inductor. The filter further includes a fifth conductive layer, located on a side of the base substrate away from the first conductive layer. The through hole is located in an area corresponding to the orthographic projection of the fifth conductive layer on the base substrate. The fifth conductive layer includes a plurality of fifth conductive lines. The fifth conductive line is connected between the first conductive column and the second conductive column in the same line. The first transfer line includes a plurality of first sub-transfer lines. The first sub-transfer line is used to form a partial coil structure of the inductor. The first sub-transfer line is connected to the first conductive column and the second conductive column in adjacent lines. Each heat dissipation column is connected to one of the first sub-transfer lines.

In an exemplary embodiment of the present disclosure, the third conductive line includes a plurality of third sub-conductive parts. The third sub-conductive parts are arranged corresponding to the first sub-transfer lines. The third sub-conductive part is connected to the corresponding first sub-transfer line through a via hole. The second conductive layer also includes: the first conductive line includes a first sub-conductive line, a second sub-conductive line, and a third sub-conductive line connected in sequence. The second sub-conductive line is used to form the first electrode of the capacitor. The first sub-conductive line is arranged corresponding to the first sub-transfer line. The first sub-conductive line is connected between the first sub-conductive line and the first sub-transfer line corresponding to the second sub-conductive line. The filter also includes a solder ball layer, located on the side of the third conductive layer away from the base substrate. The solder ball layer includes: a first solder ball, the orthographic projection of the first solder ball on the base substrate overlapping with the orthographic projection of the third sub-conductive part on the base substrate, and the first solder ball being connected to an end of the third sub-conductive part through a via hole; a second solder ball, the orthographic projection of the second solder ball on the base substrate overlapping with the orthographic projection of the third sub-conductive line on the base substrate, and the second solder ball being connected to the third sub-conductive line through a via hole; and a third solder ball, the orthographic projection of the third solder ball on the base substrate overlapping with the orthographic projection of the second conductive line on the base substrate, and the third solder ball being connected to the second conductive line through a via hole.

In an exemplary embodiment of the present disclosure, the aperture of the functional hole in the first functional area is larger than the aperture of the functional hole in the second functional area.

In an exemplary embodiment of the present disclosure, the ratio of the aperture of the through hole located in the first functional area to the aperture of the functional hole located in the second functional area is greater than or equal to 1.5 and less than or equal to 2.5.

In an exemplary embodiment of the present disclosure, the orthographic projection of the first sub-transfer line on the base substrate covers the orthographic projections of the second conductive line and the first conductive column connected thereto on the base substrate. The orthographic projection of the fifth conductive line on the base substrate covers the orthographic projections of the second conductive line and the first conductive column connected thereto on the base substrate.

In an exemplary embodiment of the present disclosure, the functional hole in the second functional area is a blind hole, and the opening of the blind hole is located on a side of the base substrate away from the first conductive layer.

In an exemplary embodiment of the present disclosure, the functional hole in the second functional area is a through hole, or the functional hole in the second functional area is a blind hole and the opening of the blind hole is located on a side of the base substrate close to the first conductive layer. The filter further includes a first insulation layer, covering the second function area of the base substrate on the side facing the first conductive layer.

In an exemplary embodiment of the present disclosure, both the thickness of the fifth conductive layer and the thickness of the second conductive layer are greater than the thickness of the first conductive layer.

In an exemplary embodiment of the present disclosure, the ratio of the thickness of the fifth conductive layer to the thickness of the first conductive layer, and the ratio of the thickness of the second conductive layer to the thickness of the first conductive layer are greater than or equal to 1.5 and less than or equal to 3.

In an exemplary embodiment of the present disclosure, the thickness of the second conductive layer is greater than or equal to 5 μm, the thickness of the first conductive layer is greater than or equal to 3 μm, and the thickness of the third conductive layer or the fifth conductive layer is greater than or equal to 5 μm.

In an exemplary embodiment of the present disclosure, the material of the heat dissipation column is copper.

In an exemplary embodiment of the present disclosure, the base substrate is a glass substrate or a silicon substrate.

According to a second aspect of the present disclosure, a method of manufacturing a filter is further provided. The filter includes an inductor and a capacitor. The first electrode of the capacitor is connected to the first end of the inductor. The manufacturing method includes: providing a base substrate; forming a plurality of functional holes on the base substrate; forming heat dissipation columns in the functional holes; forming a first conductive layer on a side of the base substrate, where the first conductive layer is insulated from at least some of the heat dissipation columns, the first conductive layer includes a first conductive line and a first transfer line, a partial structure of the first conductive line is used to form the first electrode of the capacitor, and the first transfer line is connected to a side of the first conductive line; forming a second conductive layer on the side of the first conductive layer away from the base substrate. The second conductive layer includes a second conductive line and a third conductive line. The second conductive line is arranged corresponding to the first conductive line. The orthographic projection of the second conductive line on the base substrate is located on the orthographic projection of the first conductive line on the base substrate. The second conductive line is used to form the second electrode of the capacitor. The third conductive line is located on a side of the second conductive line and is arranged corresponding to the first transfer line. The third conductive line is connected to the first transfer line through a via hole. The third conductive line is used to form a partial coil structure of the inductor.

In an exemplary embodiment of the present disclosure, forming a plurality of functional holes on the base substrate includes: irradiating the base substrate at a preset position by using a laser to modify molecular bonds at the preset position; etching the base substrate at the preset position by using an etching liquid to to form a through hole, and/or etching the base substrate at the preset position by using an etching process according to a preset aspect ratio to form a blind hole. The blind hole has a preset thickness from the bottom part of the blind hole to the other surface of the base substrate. The etching speed of the etching liquid at the preset position of the base substrate is greater than that at other positions.

In an exemplary embodiment of the present disclosure, forming the heat dissipation columns in the functional holes includes: sputtering a first material on the inner sidewall of the functional hole to form an adhesion layer; sputtering a first seed material on the adhesion layer to form a second seed layer; sputtering a heat dissipation material with a preset thickness on the second seed layer to form the heat dissipation column.

In an exemplary embodiment of the present disclosure, the functional hole is a through hole, or the functional hole is a blind hole and the opening of the blind hole is located on a side of the base substrate close to the first conductive layer. Before forming the first conductive layer on the side of the base substrate, the method further includes: depositing a first insulation material on the entire surface of the base substrate to form a first insulation layer.

In an exemplary embodiment of the present disclosure, forming the first conductive layer on the side of the base substrate includes: depositing a first conductive material with a preset thickness on the first insulation layer by using an additive method to form a first conductive material layer; forming the first conductive material layer into a first conductive layer by using a patterning process; and performing a planarization process on the first conductive layer.

In an exemplary embodiment of the present disclosure, before forming the second conductive layer on the side of the first conductive layer away from the base substrate, the method includes: depositing a first insulation material with a preset thickness on the first conductive layer by using a plasma enhanced chemical vapor deposition process to form a first dielectric layer; and depositing a first seed material with a preset thickness on the first dielectric layer by using a magnetron sputtering process to form a first seed layer. Forming the second conductive layer on the side of the first conductive layer away from the base substrate includes: depositing a second insulation material on the first conductive layer and the first seed layer by using a deposition process to form a third insulation layer; processing the third insulation layer by using a patterning process to form an opening to expose a partial structure of the first conductive layer and a partial structure of the first seed layer; depositing a first seed material at the opening by using a sputtering process to form a third seed layer; and electroplating a first conductive material with a preset thickness on the third seed layer by using an electroplating process to form a second conductive layer.

In an exemplary embodiment of the present disclosure, the filter further includes a third conductive layer. After forming a second conductive layer on a side of the first conductive layer away from the base substrate, the method further includes: depositing a second insulation material on the second conductive layer to form a fourth insulation layer; processing the fourth insulation layer by using a patterning process to form an opening to expose part of the second conductive layer located on the first conductive line; sputtering a first seed material by using a sputtering process at the fourth insulation layer located on the third conductive line and at the opening to form a fourth seed layer; electroplating a first conductive material with a preset thickness on the fourth seed layer by using an electroplating process to form a third conductive layer. The third conductive layer includes a fourth conductive line. The fourth conductive line is provided corresponding to the third conductive line. The orthographic projection of the fourth conductive line on the base substrate at least partially overlaps with the orthographic projection of the third conductive line on the base substrate. The fourth conductive line is used to form a partial coil structure of the inductor. The third conductive line and the fourth conductive line are arranged in a bending way. The orthographic projection of the third conductive line on the base substrate and the orthographic projection of the fourth conductive line on the base substrate enclose a winding area. The first end of the third conductive line is connected to the fourth conductive line through a via hole. The second end of the third conductive line is connected to the first transfer line through a via hole. The extension direction from the first end to the second end of the third conductive line is the same as the extension direction from the first end to the second end of the fourth conductive line.

In an exemplary embodiment of the present disclosure, after forming the third conductive layer, the method further includes: depositing a second insulation material on the third conductive layer to form a fifth insulation layer; forming three openings on the fifth insulation layer at positions corresponding to the fourth conductive lines by using a patterning process to expose partial structures of some of the fourth conductive lines respectively; and implanting solder balls respectively in the three openings to form a signal input terminal, a signal output terminal, and a ground terminal of the filter.

In an exemplary embodiment of the present disclosure, the base substrate includes a first functional area and a second functional area. The orthographic projection of the first transfer line on the base substrate is located in the first functional area. The orthographic projection of the first conductive line on the base substrate is located in the second functional area. The functional holes in the first functional area and the second functional area are through holes. The plurality of heat dissipation columns includes a plurality of first conductive columns and a plurality of second conductive columns. The plurality of first conductive columns and the plurality of second conductive columns are respectively arranged at intervals along the same direction. The first conductive column and the second conductive column are arranged side by side. The first conductive column and the second conductive column are used to form partial coil structures of the inductor. Before forming the first conductive layer on the side of the base substrate, the method further includes: depositing a first insulation material by using a deposition process in the second functional area of the base substrate to form a first insulation layer. Forming the first conductive layer on the side of the base substrate includes: depositing a first conductive material with a preset thickness by using an additive method on the first insulation layer and the first functional area of the base substrate to form a first conductive material layer; forming the first conductive material layer into a first conductive layer by using a patterning process; perform a planarization process on the first conductive layer.

In an exemplary embodiment of the present disclosure, the filter further includes a fifth conductive layer. The method further includes: sputtering a first seed material by using a sputtering process in the first functional area on a side of the base substrate away from the first conductive layer to form a fifth seed layer; electroplating a first conductive material with a preset thickness on the fifth seed layer by using an electroplating process to form a fifth conductive layer; and processing the fifth conductive layer by using a patterning process to form a plurality of first sub-transfer lines. The first sub-transfer line is used to form a partial coil structure of the inductor. The first sub-transfer line is connected between the first conductive column and the second conductive column in adjacent lines. Each heat dissipation column is connected to one of the first sub-transfer lines.

According to a third aspect of the present disclosure, an electronic device is also provided, including the filter described in any embodiment of the present disclosure.

In the filter provided by the present disclosure, the functional hole is formed on the base substrate, and filled with the heat dissipation column having high thermal conductivity. Besides, at least some of the heat dissipation columns are arranged to be insulated from the first conductive layer, so that these heat dissipation columns are used to improve the heat dissipation performance of the base substrate, thereby improving the overall heat dissipation performance of the filter.

It should be understood that the foregoing general description and the following detailed description are exemplary and explanatory only, and do not limit the present disclosure.

### BRIEF DESCRIPTION OF THE DRAWINGS

The accompanying drawings, which are incorporated in and constitute a part of this specification, illustrate embodiments consistent with the present disclosure and together with the description, serve to explain the principles of the present disclosure. It is noted that the drawings in the following description are only some embodiments of the present disclosure. For those of ordinary skill in the art, other drawings can be obtained based on these drawings without exerting creative efforts.

FIG. 1 is an equivalent circuit diagram of a filter according to an embodiment of the present disclosure;

FIG. 2 is a structural layout of a filter according to an embodiment of the present disclosure;

FIG. 3 shows the layout structure of the base substrate in FIG. 2;

FIG. 4 is the layout structure of the first conductive layer in FIG. 2;

FIG. 5 is the layout structure of the second conductive layer in FIG. 2;

FIG. 6 shows the layout structure of the third conductive layer in FIG. 2;

FIG. 7 shows the layout structure of the solder ball layer in FIG. 2;

FIG. 8 is a stacked layout structure of the first conductive layer and the second conductive layer in FIG. 2;

FIG. 9 is a stacked layout structure of the second conductive layer and the third conductive layer in FIG. 2;

FIG. 10 is a stacked layout structure of the first conductive layer, the first dielectric layer, and the first seed layer in FIG. 2;

FIG. 11 is a partial cross-sectional view along the dotted line MM in FIG. 2;

FIG. 12a is a cross-sectional view of a base substrate according to an embodiment of the present disclosure;

FIG. 12b is a cross-sectional view of a base substrate according to another embodiment of the present disclosure;

FIG. 13a is a schematic bending diagram of the first transfer line, the third conductive line, and the fourth conductive line according to an embodiment of the present disclosure;

FIG. 13b is a schematic bending diagram of the first transfer line, the third conductive line, and the fourth conductive line according to another embodiment of the present disclosure;

FIG. 14 is a structural layout of a filter according to another embodiment of the present disclosure;

FIG. 15 is the layout structure of the base substrate in FIG. 14;

FIG. 16 is the layout structure of the first conductive layer in FIG. 14;

FIG. 17 is the layout structure of the second conductive layer in FIG. 14;

FIG. 18 shows the layout structure of the solder ball layer in FIG. 14;

FIG. 19 is the layout structure of the fifth conductive layer in FIG. 14;

FIG. 20 is a cross-sectional view along the dotted line NN in FIG. 14;

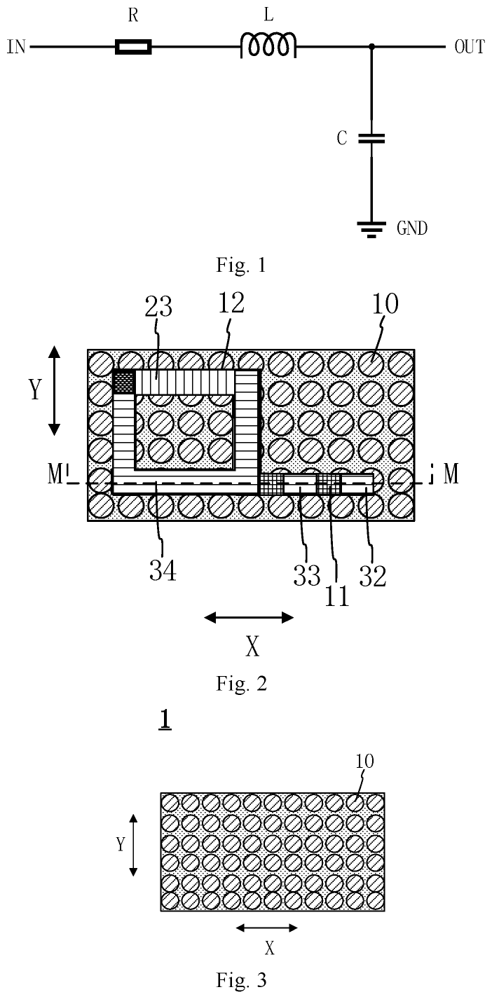

FIG. 2la is a cross-sectional view of a base substrate according to an embodiment of the present disclosure;

FIG. 21b is a cross-sectional view of a base substrate according to another embodiment of the present disclosure; and

FIGS. 22 to 27f are process flow diagrams of a method for manufacturing a filter according to another embodiment of the present disclosure.

### DETAILED DESCRIPTION OF THE EMBODIMENTS

Example embodiments will now be described more fully with reference to the accompanying drawings. Example embodiments may, however, be embodied in various forms and should not be construed as limited to the embodiments set forth herein. Rather, these embodiments are provided so that the present disclosure will be thorough and complete, and will fully convey the concepts of the example embodiments to those skilled in the art. The same reference numerals in the drawings indicate the same or similar structures, and thus their detailed descriptions will be omitted. Furthermore, the drawings are merely schematic illustrations of the present disclosure and are not necessarily drawn to scale.

An exemplary embodiment provides a filter. FIG. 1 is an equivalent circuit diagram of a filter according to an embodiment of the present disclosure. As shown in FIG. 1, the filter may include a capacitor C, an inductor L, and a resistor R. The first terminal of the inductor L is connected to the first electrode of the capacitor C, and the second terminal of the inductor L is connected to the signal input terminal IN through the resistor R. The second electrode of the capacitor C is connected to the ground terminal GND. The second terminal of the inductor L and the first electrode of the capacitor C are connected to the signal output terminal OUT.

The filter provided by the present disclosure may include a base substrate, a heat dissipation column, a first conductive layer, and a second conductive layer. The base substrate has at least one functional hole. The heat dissipation column is provided corresponding to the functional hole. The heat dissipation column is filled in the corresponding function hole. The first conductive layer is located on a side of the base substrate. The first conductive layer may include a first conductive line and a first transfer line. A partial structure of the first conductive line is used to form the first electrode of the capacitor C. The first transfer line is connected to a side of the first conductive line. A partial structure of the first transfer line is used to form a partial coil structure of the inductor L. The second conductive layer is located on the side of the first conductive layer away from the base substrate. The second conductive layer may include a second conductive line and a third conductive line. The second conductive line is arranged corresponding to the first conductive line. The orthographic projection of the second conductive line on the base substrate is located on the orthographic projection of the first conductive line on the base substrate. The second conductive line is used to form the second electrode of the capacitor C. The third conductive line is located on a side of the second conductive line, and is provided corresponding to the first transfer line. The third conductive line is connected to the first transfer line through a via hole. The third conductive line is used to form a partial coil structure of the inductor L. At least some of the heat dissipation columns are insulated from the first conductive layer. The thermal conductivity of the heat dissipation column is greater than the thermal conductivity of the base substrate.

In the filter provided by the present disclosure, the functional hole is formed on the base substrate, and filled with the heat dissipation column having a relatively high thermal conductivity. Further, at least some of the heat dissipation columns are arranged to be insulated from the first conductive layer, so that these heat dissipation columns are used to improve the heat dissipation performance of the base substrate, thereby improving the overall heat dissipation performance of the filter.

In the filter provided by the present disclosure, the inductor L may be a three-dimensional inductor L or a two-dimensional inductor L. The three-dimensional inductor L uses the conductive characteristic of the heat dissipation column, and the heat dissipation column form a partial coil structure of the inductor L. The two-dimensional inductor L completely uses the wiring of the conductive layer to form the coil structure of the inductor L, and the heat dissipation column only acts as the heat dissipation structure of the filter. Considering that there are certain differences in the structural layouts of the three-dimensional inductor L and the two-dimensional inductor L, the filter structure with the three-dimensional inductor L and the filter structure with the two-dimensional inductor L will be described separately below with reference to the accompanying drawings.

In an exemplary embodiment, a filter with a two-dimensional inductor L may include: a base substrate; and a first conductive layer, a second conductive layer, a third conductive layer, and a solder ball layer that are sequentially stacked on a side of the base substrate.

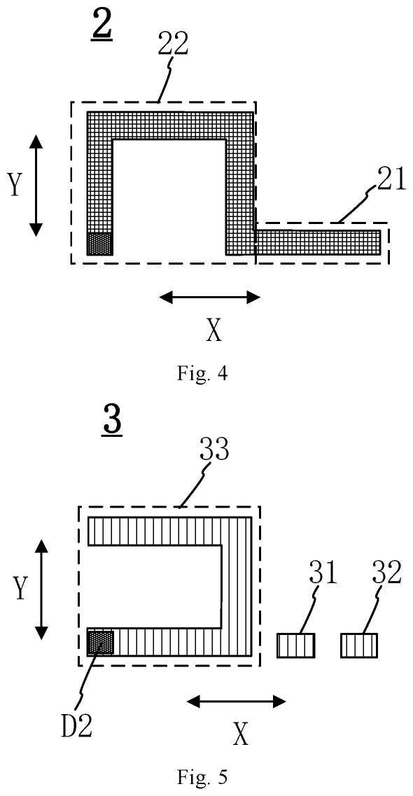

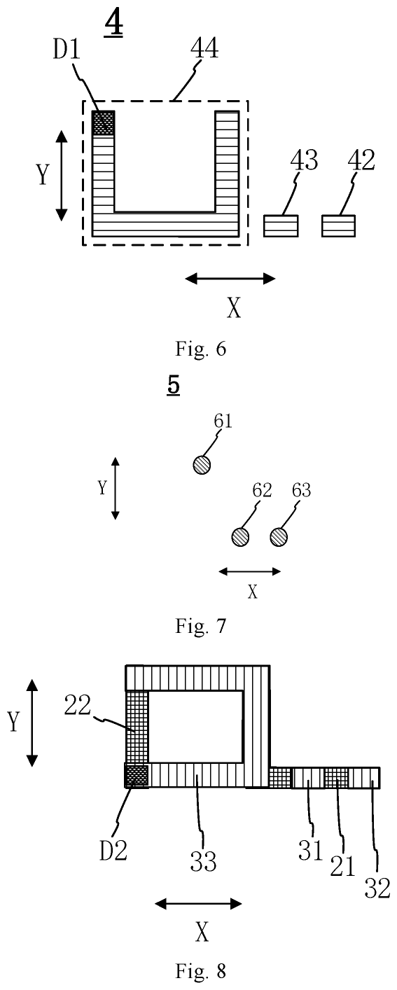

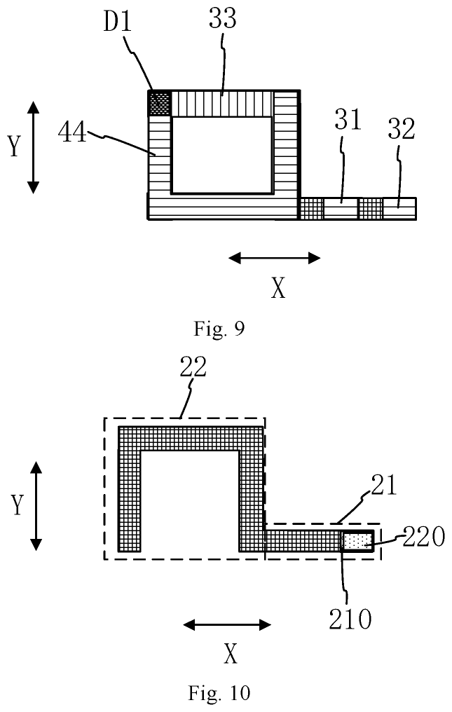

As shown in FIGS. 2-12, FIG. 2 is a structural layout of a filter according to an embodiment of the present disclosure, FIG. 3 is a layout structure of the base substrate in FIG. 2, FIG. 4 is a layout structure of the first conductive layer in FIG. 2, FIG. 5 is the layout structure of the second conductive layer in FIG. 2, FIG. 6 is the layout structure of the third conductive layer in FIG. 2, FIG. 7 is the layout structure of the solder ball layer in FIG. 2, FIG. 8 is the stacked layout structure of the first conductive layer and the second conductive layer in FIG. 2, FIG. 9 is the stacked layout structure of the second conductive layer and the third conductive layer in FIG. 2, FIG. 10 is the stacked layout structure of the first conductive layer, the first dielectric layer, and the first seed layer in FIG. 2, and FIG. 11 is a partial cross-sectional view along the dotted line MM in FIG. 2.

In an exemplary embodiment, the first direction X may be the row direction X shown in the figures, the second direction Y may be the column direction Y shown in the figures, and the first direction X intersects the second direction Y.

In an exemplary embodiment, as shown in FIGS. 2 and 3, the base substrate 1 may be a glass substrate or a silicon substrate. The base substrate 1 includes a plurality of functional holes distributed in an array. Each functional hole is filled with a heat dissipation column 10. The thermal conductivity of the heat dissipation column 10 is greater than the thermal conductivity of the base substrate 1. At least some of the heat dissipation columns 10 are insulated from the first conductive layer 2. Thus, the heat dissipation column 10 which is insulated from the first conductive layer 2 can form a heat dissipation structure of the filter, and this improves the heat dissipation effect of the filter. Generally, metal conductive materials have high thermal conductivity. Therefore, the heat dissipation column 10 in an exemplary embodiment may be formed of metal conductive material. For example, a copper conductive column may be formed of copper material as the heat dissipation column 10. It should be understood that this is only an exemplary description, and should not be understood as any limitation on the material of the heat dissipation column 10 in the present disclosure. Any other material having a higher thermal conductivity than the base substrate 1 may form the heat dissipation column 10 of the present disclosure. The heat dissipation column 10 described in the present disclosure may be a hollow heat dissipation column 10, and the extension direction of the cavity of the heat dissipation column 10 is the same as the extension direction of the heat dissipation column 10. The heat dissipation column 10 may also be a solid heat dissipation column 10, and the solid heat dissipation column 10 can have better heat dissipation effect.

The functional hole may be a through hole TGV or a blind hole BGV. The through hole TGV is a hole that penetrates the two opposite sides of the base substrate 1. In a filter structure including the two-dimensional inductor L, the heat dissipation column 10 is only used as a heat dissipation structure. Thus, it is necessary to electrically isolate the heat dissipation column 10 filled in the through hole TGV from the first conductive layer 2. Accordingly, the filter may also include a first insulation layer 100. The first insulation layer 100 may be obtained by depositing on the entire surface. That is, the first insulation layer 100 is obtained by depositing a first insulation material on the entire side surface of the base substrate 1 facing the first conductive layer 2. The first insulation material may be, for example, SiNx.

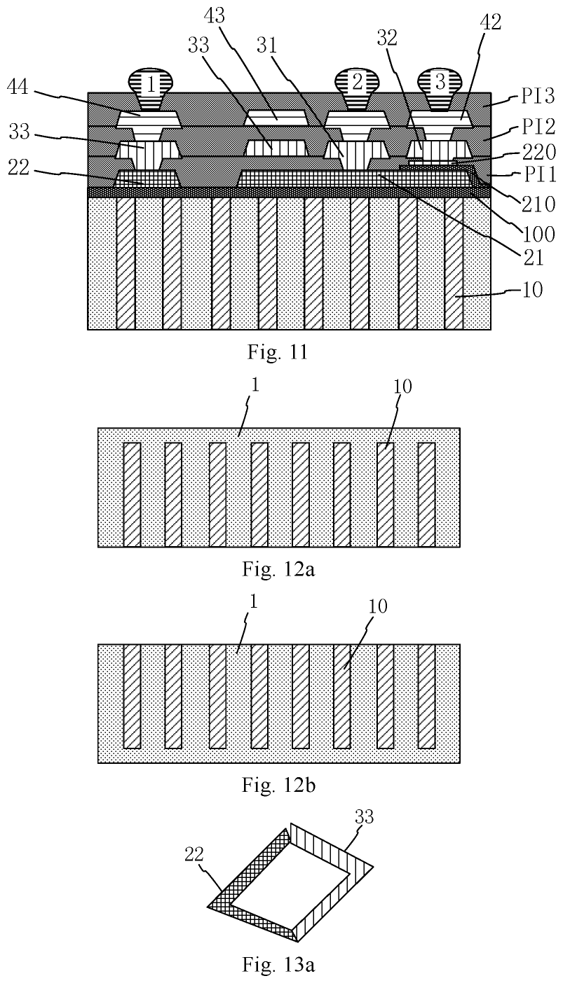

FIG. 12a is a cross-sectional view of a base substrate according to an embodiment of the present disclosure. FIG. 12b is a cross-sectional view of a base substrate according to another embodiment of the present disclosure. As shown in FIGS. 12a and 12b, the blind hole BGV is a hole that only penetrates one surface of the base substrate 1, but does not penetrate the other surface. In other words, the blind hole BGV has an opening and a bottom part. The opening is located on one surface of the base substrate 1, and extends from the surface where the opening is located along the thickness direction of the base substrate to the other surface of the base substrate. The bottom part of the blind hole BGV is formed at a certain distance from the other surface of the base substrate. When the functional hole is a blind hole BGV, the bottom part of the functional hole may be facing the first conductive layer 2 as shown in FIG. 12a. That is, the opening is located on the side of the base substrate away from the first conductive layer. Thus, the remaining thickness of the base substrate 1 is used to achieve the electrical isolation between the heat dissipation column 10 and the first conductive layer 2. It is noted that as shown in FIG. 12b, the bottom part of the blind hole BGV may also be arranged away from the first conductive layer 2. That is, the opening of the blind hole BGV is located on the side of the base substrate close to the first conductive layer. In this case, a first insulation material may be deposited on the entire side surface of the base substrate 1 facing the first conductive layer 2 to form a first insulation layer 100. The first insulation layer 100 is used to achieve the electrical isolation between the first conductive layer 2 and the heat dissipation column 10.

It can be understood that when the opening of the blind hole BGV is located on the side of the base substrate away from the first conductive layer, there is a certain thickness distance between the bottom part of the blind hole BGV and this structure, and the thickness distance is the remaining thickness of the base substrate 1 at the position of the blind hole BGV.

In addition, it can be understood that the different distribution density of the functional holes in the base substrate 1 will affect the heat dissipation performance of the filter. When the distribution density of the functional holes is higher, it is equivalent to having more heat dissipation columns 10 per unit area. Therefore, by increasing the distribution density of functional holes, the heat dissipation performance of the filter can be improved.

In an exemplary embodiment, as shown in FIGS. 2 and 4, the first conductive layer 2 may include a first transfer line 22 and a first conductive line 21. The orthographic projection of the first conductive line 21 on the base substrate 1 may extend along the first direction X. A partial structure of the first conductive line 21 may be used to form a first electrode of the capacitor C. The first transfer line 22 is connected to one end of the first conductive line 21. The first transfer line 22 may be connected to the third conductive line 33 (used to form a partial coil structure of the inductor L) in the second conductive layer 3 through a via hole. Thus, through the connection between the first transfer line 22 and the first conductive line 21, the first end of the inductor L is connected to the first electrode of the capacitor C.

In an exemplary embodiment, as shown in FIGS. 2 and 5, the second conductive layer 3 may include a second conductive line 32 and a third conductive line 33. The orthographic projection of the second conductive line 32 on the base substrate 1 may be located on the orthographic projection of the first conductive line 21 on the the base substrate 1. For example, the orthographic projection of the second conductive line 32 on the base substrate 1 is located within the orthographic projection of the first conductive line 21 on the base substrate 1. The second conductive line 32 is arranged opposite to the first conductive line 21 to form two electrodes of the capacitor C. The third conductive line 33 may be bent to form a partial coil structure of the inductor L. As mentioned above, the third conductive line 33 may be connected to the first transfer line 22 in the first conductive layer through a via hole (the blackened position D2 in FIGS. 5 and 8). The second conductive layer 3 may also include a first connection part 31. The first connection part 31 is located between the second conductive line 32 and the third conductive line 33, and is provided corresponding to the first conductive line 21. For example, the orthographic projection of the first connection part 31 on the base substrate 1 may be located on the orthographic projection of the first conductive line 21 on the base substrate 1. As shown in FIG. 11, the first connection part 31 may be connected to the first conductive line 21 through a via hole, so that the first connection part 31 is connected to the first end of the inductor L and the first electrode of the capacitor C. The first connection part 31 is further connected to the third connection part 43 of the third conductive layer 4 and the second solder ball 2 of the solder ball layer 5 through a via hole to form the signal output terminal OUT in FIG. 1.

In an exemplary embodiment, as shown in FIGS. 2 and 6, the third conductive layer 4 may include the fourth conductive line 44 arranged corresponding to the third conductive line 33. The orthographic projection of the fourth conductive line 44 on the base substrate 1 and the orthographic projection of the third conductive line 33 on the base substrate 1 may partially overlap. The fourth conductive line 44 may be used to form a partial coil structure of the inductor L. The fourth conductive line 44 may be connected to the third conductive line 33 through a via hole (the blackened position DI in FIGS. 6 and 9). The third conductive layer 4 may also include a second connection part 42 and a third connection part 43. The second connection part 42 is provided corresponding to the second conductive line 32 in the second conductive layer 3. The orthographic projection of the second connection part 42 on the base substrate 1 may partially overlap with the orthographic projection of the second conductive line 32 on the base substrate 1. As shown in FIG. 11, the second connection part 42 may be connected to the second conductive line 32 through a via hole, so that the second electrode of the capacitor C is led out and then connected to the ground terminal GND through the third solder ball 3 of the solder ball layer 5. The third connection part 43 is provided corresponding to the first connection part 31. The orthographic projection of the third connection part 43 on the base substrate 1 may partially overlap with the orthographic projection of the first connection part 31 on the base substrate 1. As shown in FIG. 11, the third connection part 43 may be connected to the first connection part 31 through a via hole. As mentioned above, the signal output terminal OUT in FIG. 1 is formed after the third connection part 43 is connected to the second solder ball 2 at the corresponding position.

In an exemplary embodiment, as shown in FIGS. 2 and 7, the solder ball layer 5 may include a first solder ball 1, a second solder ball 2, and a third solder ball 3. The orthographic projection of the first solder ball 1 on the base substrate 1 may partially overlap with the orthographic projection of the fourth conductive line 44 on the base substrate 1. The first solder ball 1 may be connected to one end of the fourth conductive line 44 through a via hole to form the signal input terminal IN in FIG. 1. The orthographic projection of the second solder ball 2 on the base substrate 1 may overlap with the orthographic projection of the third connecting part 43 on the base substrate 1. The second solder ball 2 may be connected to the third connecting part 43 through a via hole, forming the signal output terminal OUT in FIG. 1. The orthographic projection of the third solder ball 3 on the base substrate 1 may partially overlap with the orthographic projection of the second connection part 42 on the base substrate 1. The third solder ball 3 may be connected to the second connection part 42 through a via hole, so that the second electrode of the capacitor C is connected to the ground terminal GND.

As shown in FIGS. 2, 5, and 6, the third conductive line 33 and the fourth conductive line 44 are arranged in a bending way respectively. The orthographic projection of the third conductive line 33 on the base substrate 1 and the orthographic projection of the fourth conductive line 44 on the base substrate 1 enclose a winding area. The first end of the third conductive line 33 may be connected to the first end of the fourth conductive line 44 through a via hole. The second end of the third conductive line 33 may be connected to the first transfer line 22 through a via hole. The extension direction from the first end to the second end of the third conductive line 33 is the same as the extension direction from the first end to the second end of the fourth conductive line 44. Therefore, the third conductive line 33 and the fourth conductive line 44 form a spiral winding structure as a whole.

It can be understood that the extension direction from the first end to the second end of a certain conductive line described in the present disclosure can be understood as the moving direction of any point on the conductive line while moving from the first end to the second end. It may be clockwise or counterclockwise.

In an exemplary embodiment, by disposing the first transfer line 22 of the first conductive layer 2 in a bending way, the first transfer line 22 may also form a partial coil structure of the inductor L. When the first transfer line 22, the third conductive line 33, and the fourth conductive line 44 jointly form the coil structure of the inductor L, as shown in FIG. 9, the first transfer line 22, the third conductive line 33, and the fourth conductive line 44 form a spiral structure as a whole. One end of the spiral structure is connected to the first conductive line 21 by the first transfer line 22, so that the first end of the inductor L is connected to the first electrode of the capacitor C. The other end of the spiral structure is connected to the second solder ball 2 of the solder ball layer 5 by an end of the fourth conductive line 44, so that the second end of the inductor L is connected to the signal input terminal IN through the resistor.

Exemplarily, as shown in FIGS. 4 to 6, 8, and 9, the first transfer line 22, the third conductive line 33, and the fourth conductive line 44 are respectively arranged in a bending way. The first transfer line 22 starts bending in the counterclockwise direction from the leading end connected to the first conductive line 21, and has its trailing end connected to the leading end of the third conductive line 33 through a via hole. After the third conductive line 33 is also bent in the counterclockwise direction, its trailing end is connected to the leading end of the fourth conductive line 44 through a via hole. After the fourth conductive line 44 is bent, its trailing end is connected to the solder ball at the corresponding position of the solder ball layer 5. At this time, the orthographic projections on the base substrate 1 of the first transfer line 22, the third conductive line 33, and the fourth conductive line 44 form a winding area. The first transfer line 22, the third conductive line 33, and the fourth conductive line 44 form a spirally extending winding as a whole, thereby forming a coil structure of the inductor L.

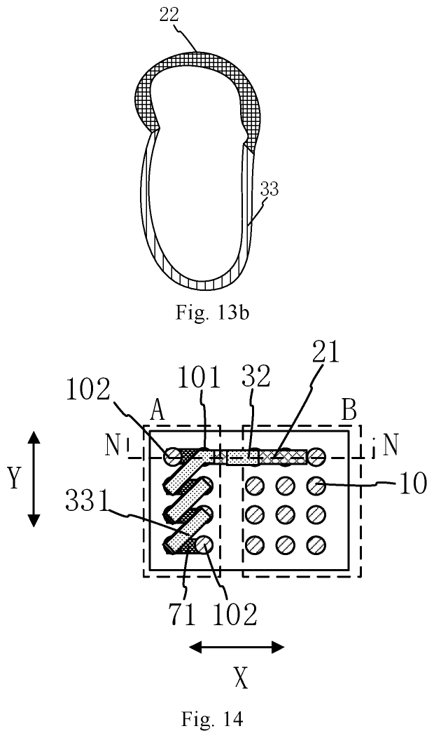

FIG. 13a is a schematic bending diagram of the first transfer line, the third conductive line, and the fourth conductive line according to an embodiment of the present disclosure. FIG. 13b is a schematic bending diagram of the first transfer line, the third conductive line, and the fourth conductive line according to another embodiment of the present disclosure. It can be understood that the first transfer line 22, the third conductive line 33, and the fourth conductive line 44 may be bent in a regular shape, such as a U-shape, a circular shape, etc., or may be bent in an irregular shape. For example, they may be bent in the way shown in FIG. 13a and FIG. 13b, but the present disclosure is not limited thereto. By arranging the third conductive line 33 and the fourth conductive line 44 into a regular bent shape, the difficulty in wiring can be simplified, which is beneficial to adjusting the parameter of the inductor L.

In an exemplary embodiment, the base substrate 1 may further include an adhesion layer and a second seed layer. A first material may be sputtered on the sidewall of the functional hole through a sputtering process to form an adhesion layer. The first material may be, for example, Ti. That is, a Ti adhesion layer is formed on the inner wall of the functional hole by sputtering Ti material. The thickness of the adhesion layer may be greater than 5 nm. The second seed layer is then formed by sputtering the first seed material on the Ti adhesion layer. The thickness of the second seed layer may be greater than 30 nm. The first seed material may be copper, for example. Then, a double-side Cu electroplating process is performed on the through hole TGV in a butterfly-shaped way to form a heat dissipation column 10 with a preset thickness. It should be understood that the first seed material may also be other materials.

In an exemplary embodiment, the thickness of the base substrate 11 may be 0.25 mm to 0.35 mm. For example, the thickness of the base substrate 1 may be 0.25 mm, 0.27 mm, 0.3 mm, 0.35 mm, etc. The cross-section of the functional hole in a plane parallel to the base substrate 1 may be circular. The ratio of the length of the functional hole along the thickness direction of the base substrate 1 to the aperture of the functional hole may be greater than or equal to 5 and less than or equal to 7. For example, the ratio may be 5, 5.5, 6, 6.5, 7, etc. The aperture of the functional hole may be 50 μM to 80 μM. For example, the aperture of the functional hole may be 50 μM, 60 μM, 70 μM or 80 μM. The thickness of the adhesion layer located between the second seed layer and the sidewall of the functional hole may be 5 nm to 30 nm. For example, the thickness of the adhesion layer may be 5 nm, 10 nm, 15 nm, 25 nm, 30 nm, etc. The thickness of the second seed layer may be 30 nm to 80 nm. For example, the thickness of the second seed layer may be 30 nm, 50 nm, 70 nm, 80 nm, etc. It should be understood that in other exemplary embodiments, the cross-section of the functional hole in a plane parallel to the base substrate 1 may also be in other shapes, such as rectangle, rhombus, etc.

On the basis of the above embodiments, the functional holes on the base substrate 1 may have different shapes. For example, the functional holes on the base substrate 1 may be formed by laser drilling. Accordingly, the opening areas of the functional holes at various positions in the thickness direction of the base substrate 1 may be the same. In addition, the base substrate 1 may also be formed through a wet etching process. For example, a laser may be used to irradiate the base substrate 1 at a preset position to modify the molecular bonds at the preset position of the base substrate 1. The etching speed at the preset position of the base substrate 1 will be greater than the etching speed at other positions of the base substrate 1. Then, the etching liquid is used to etch the base substrate 1 at the preset position to form the functional holes. In an exemplary embodiment, an etching liquid may be used to etch functional holes from one side to the other side of the glass substrate. Accordingly, the opening area of the functional hole gradually decreases from one opening to the other opening. In another exemplary embodiment, the etching liquid may also be used to etch functional holes from both sides of the base substrate 1 toward the middle position. Accordingly, the opening area of the functional hole may gradually decrease from the two openings to the middle position. The wet etching process enables the sidewall of the functional hole to be smoother, thereby facilitating the bonding of the adhesion layer and the second seed layer with the sidewall of the functional hole.

It should be understood that regardless of whether the functional hole is a through hole TGV or a blind hole BGV, it may have the functional hole structure and its effect described above.

In addition, the shape of the heat dissipation column 10 located in the functional hole may match the shape of the functional hole. That is, the radial sizes of the heat dissipation column 10 at various positions are the same, or the radial size of the heat dissipation column 10 may gradually decrease from one side of the base substrate 1 toward the other side of the base substrate 1, or the radial size of the heat dissipation column 10 may gradually decrease from both sides of the base substrate 1 to a middle position.

In an exemplary embodiment, the thickness of the second conductive layer 3 and the thickness of the third conductive layer 4 may be greater than the thickness of the first conductive layer 2. The thickness of the second conductive layer 3 and the thickness of the third conductive layer 4 may be 1.5 times to 3 times the thickness of the first conductive layer 2, and for example, may be 1.5 times, 2 times, 2.5 times, 3 times, etc. The thickness of the first conductive layer 2 may be, for example, 3 μm or more. The thickness of the second conductive layer 3 and the thickness of the third conductive layer 4 may be, for example, 5 μm or more. Since the second conductive layer 3 and the third conductive layer 4 are to used to form the coil structure of the inductor L, by increasing the thicknesses of the second conductive layer 3 and the third conductive layer 4, the inductor L value of the formed inductor L can be increased, and the loss of the inductor L can be reduced, thereby improves the filtering effect of the filter.

In an exemplary embodiment, as shown in FIGS. 10 and 11, the filter may further include a first dielectric layer 210 and a first seed layer 220 stacked on the first conductive layer 2 in sequence. The first dielectric layer 210 is arranged corresponding to the second conductive line 32. The orthographic projection of the first dielectric layer 210 on the base substrate 1 covers the orthographic projection of the second conductive line 32 on the base substrate 1. The first dielectric layer 210 is used to form the dielectric layer of the capacitor C. The plasma enhanced chemical vapor deposition (PECVD) process may be used to deposit a high-flatness SiNx film of 120 nm as the dielectric layer of the capacitor C, thereby ensuring the uniformity of the capacitor C. A Cu film of 100 nm may be deposited by using a magnetron sputtering process on the first dielectric layer 210 as a second electrode pad for the capacitor C and a seed layer for generating the second electrode of the capacitor C.

In an exemplary embodiment, a filter with a three-dimensional inductor L may include: a base substrate 1; a first conductive layer 2, a second conductive layer 3, and a solder ball layer 5 stacked on one side of the base substrate in sequence; and a fifth conductive layer 6 located on the other side of the base substrate 1.

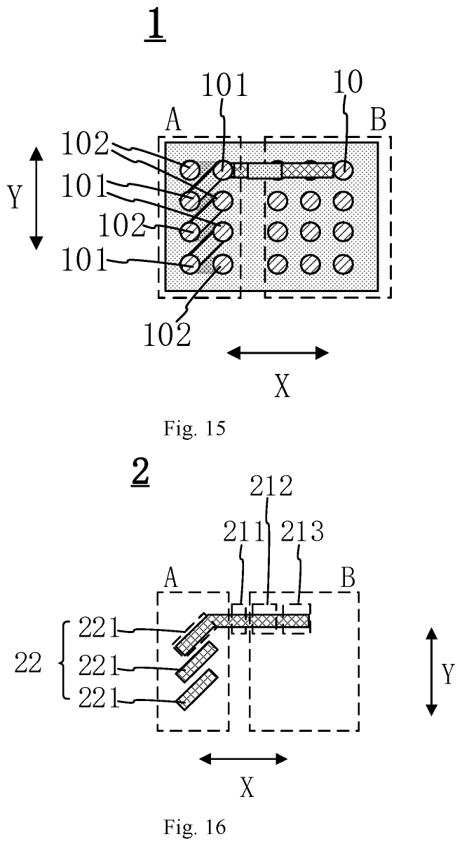

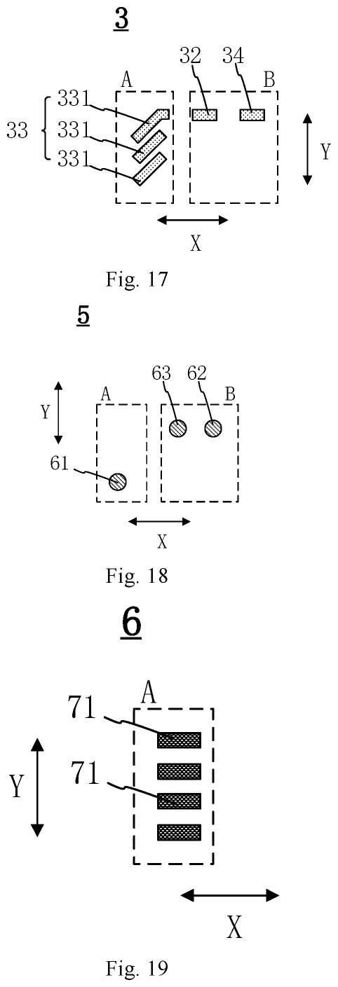

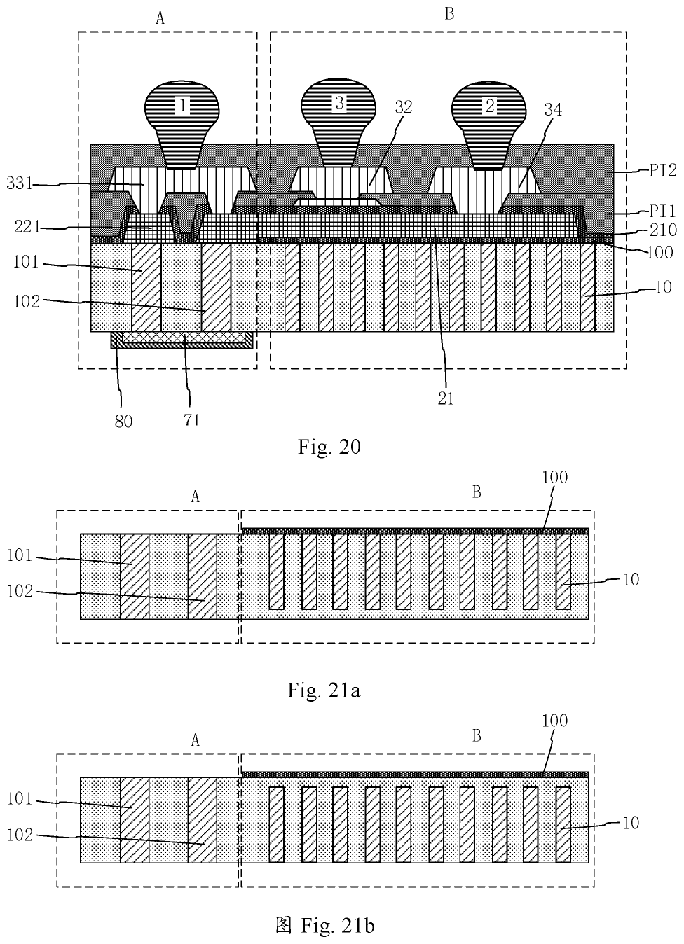

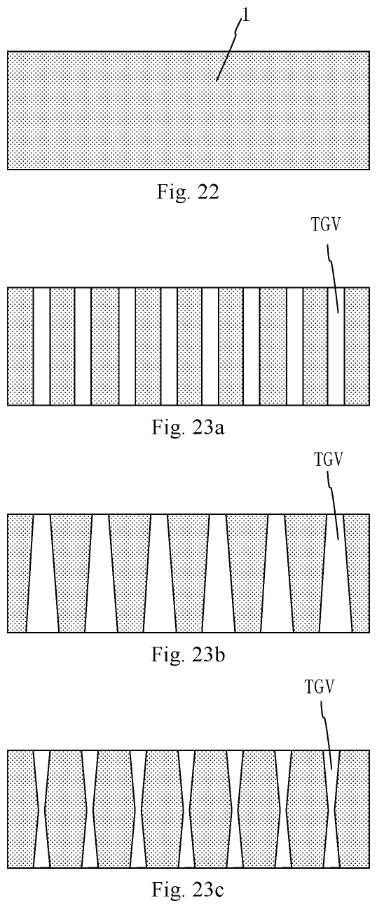

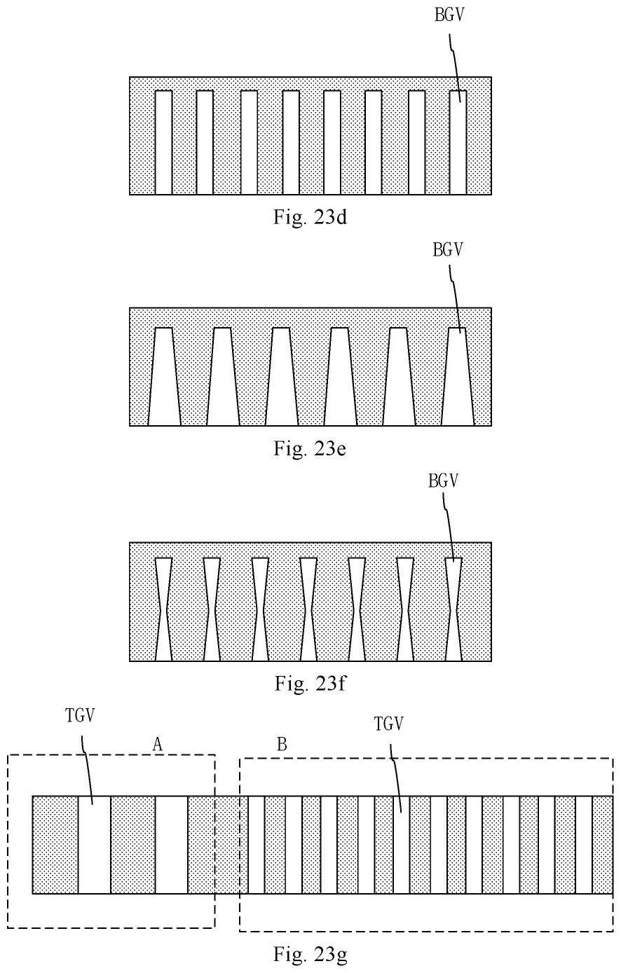

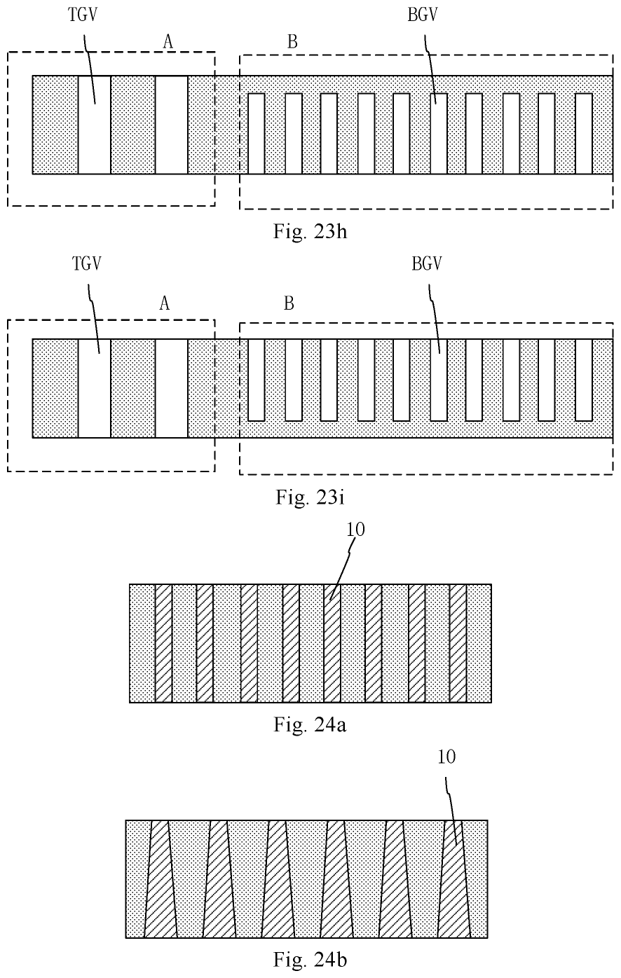

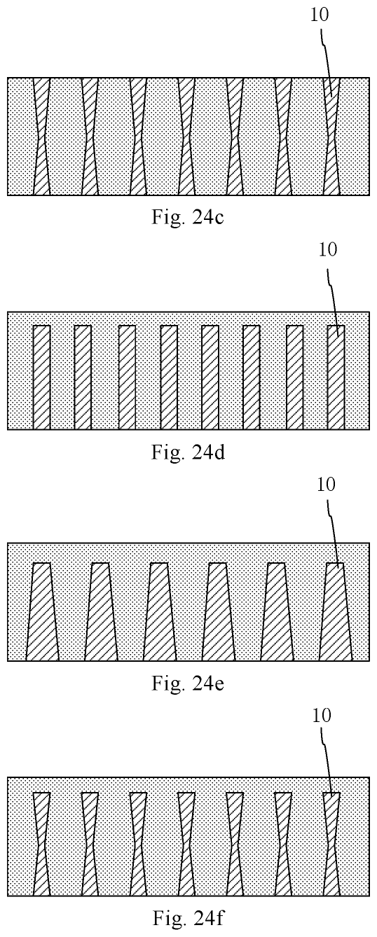

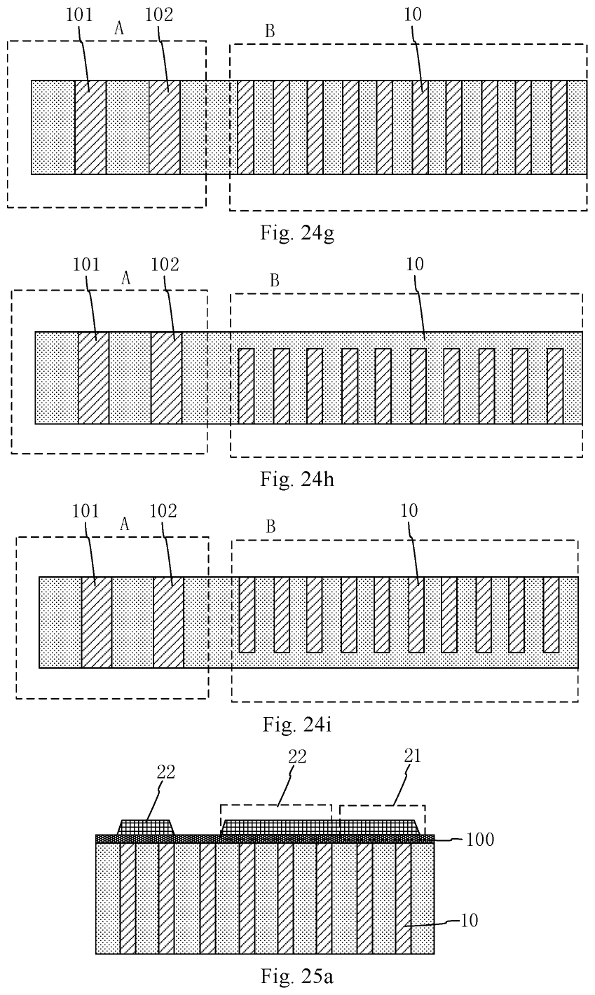

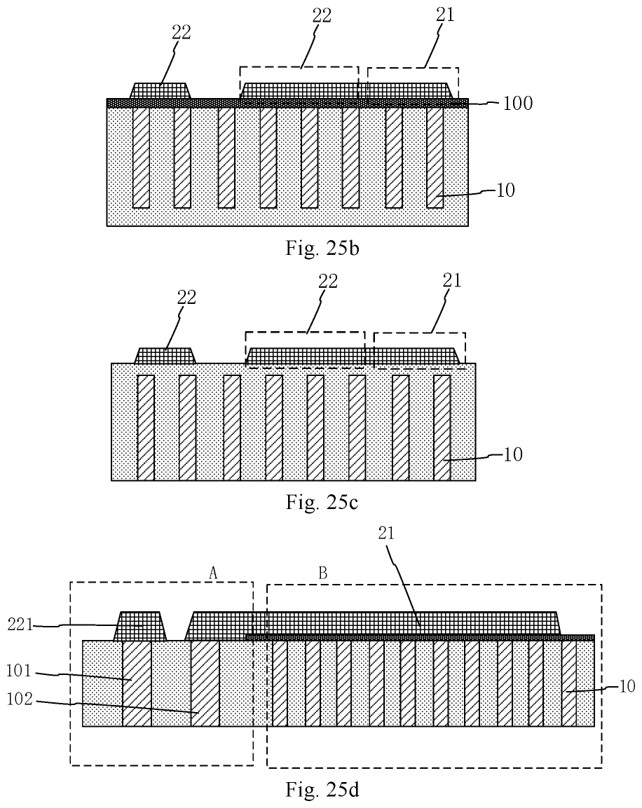

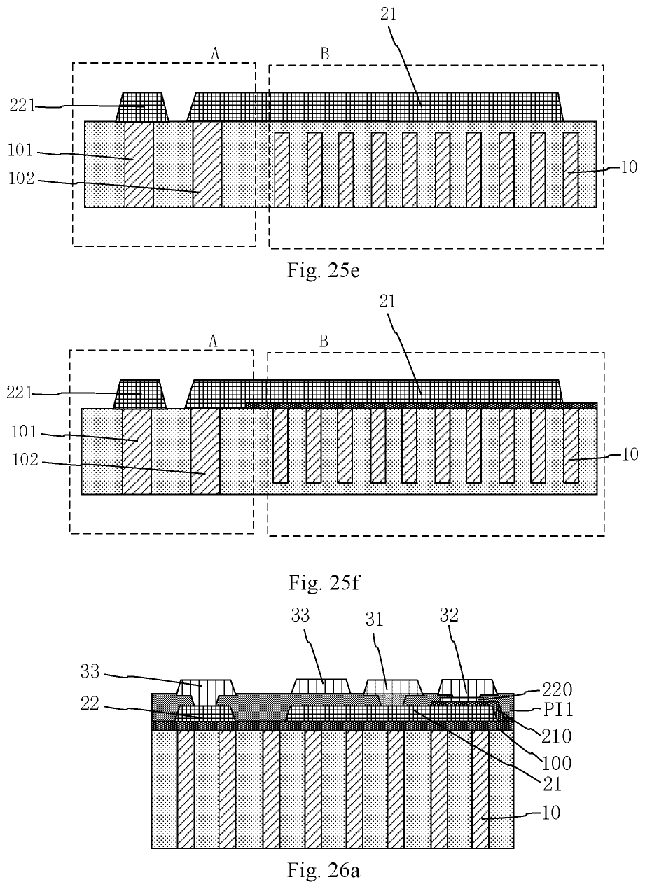

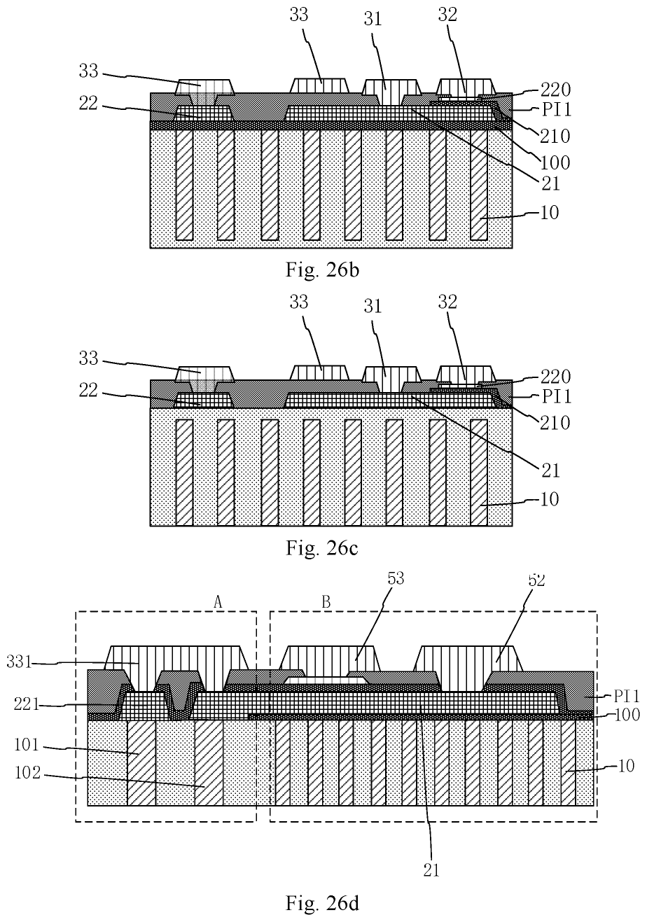

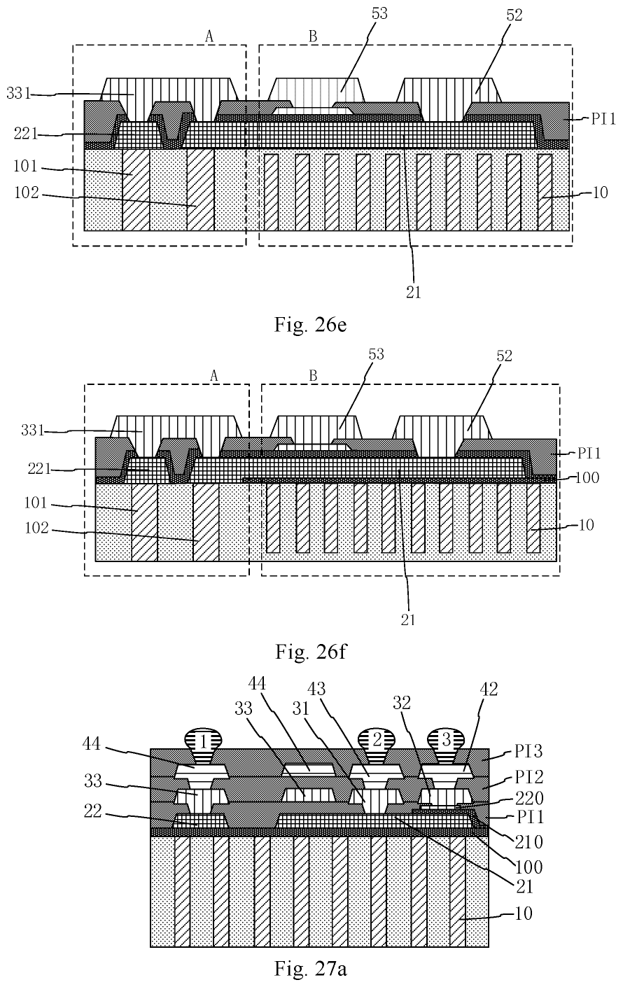

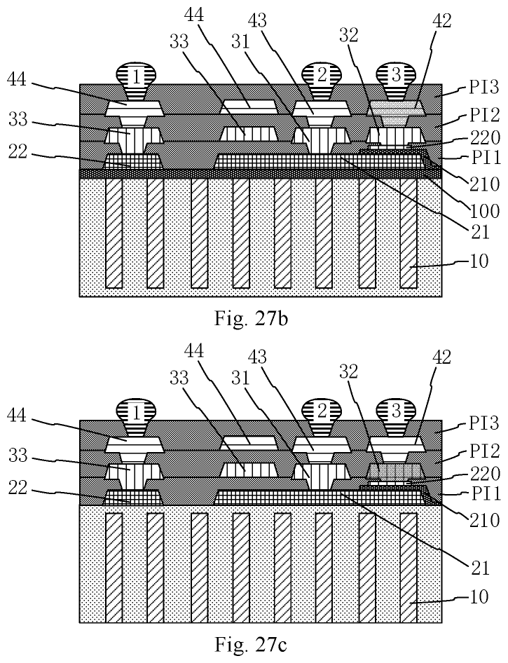

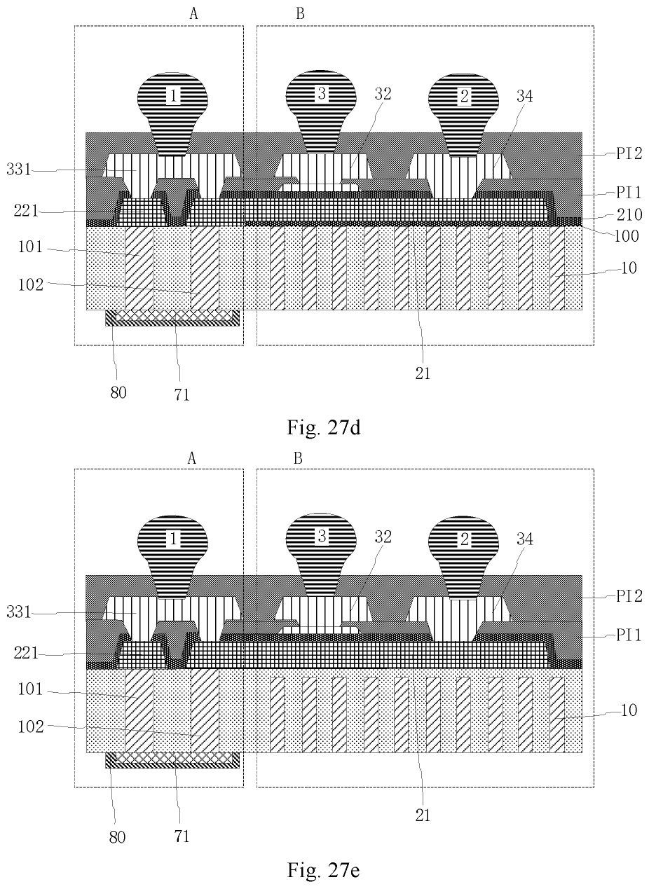

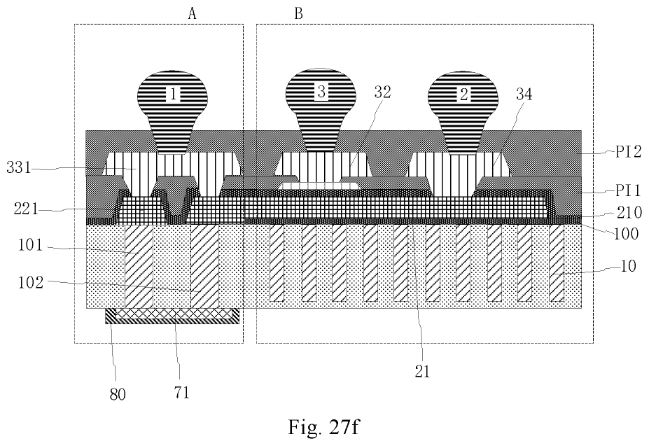

As shown in FIGS. 14 to 23, FIG. 14 is a structural layout of a filter according to another embodiment of the present disclosure, FIG. 15 is a layout structure of the base substrate in FIG. 14, FIG. 16 is a layout structure of the first conductive layer in FIG. 14, FIG. 17 is a layout structure of the second conductive layer in FIG. 14, FIG. 18 is a layout structure of the solder ball layer in FIG. 14, FIG. 19 is a layout structure of the fifth conductive layer in FIG. 14, and FIG. 20 is a cross-sectional view along the dashed line NN in FIG. 14.

In an exemplary embodiment, as shown in FIGS. 14 and 15, the base substrate 1 may be a glass substrate or a silicon substrate. The base substrate 1 may include a first functional area A and a second functional area B. The first functional area A is distributed with a plurality of first conductive columns 101 and a plurality of second conductive columns 102. The plurality of first conductive columns 101 and the plurality of second conductive columns are arranged at intervals along the same direction respectively. For example, they may be arranged at intervals along the second direction Y in the figures. The first conductive column 101 and the second conductive column 102 are arranged side by side. The functional hole in the first functional area A is a through hole TGV. In this case, the conductive column located in the through hole TGV may form an electrical connection with the transfer line and the conductive line connected thereto, so that the conductive column forms a partial coil structure of the inductor L.

The heat dissipation column 10 located in the second functional area B is only used to form the heat dissipation structure of the filter. The functional hole in the second functional area B may be a through hole TGV or a blind hole BGV.

FIG. 21 a is a cross-sectional view of a base substrate according to an embodiment of the present disclosure, and FIG. 21 b is a cross-sectional view of a base substrate according to another embodiment of the present disclosure. As shown in FIG. 20, when the functional hole in the second functional area B is a through hole TGV. Alternatively, as shown in FIG. 21a, the functional hole in the second functional area B is a blind hole BGV, and the opening of the blind hole BGV is located on a side of the base substrate 1 close to the first conductive layer 2. In this case, as similar to the filter structure of the two-dimensional inductor L mentioned above, the first insulation layer 100 is formed on the side of the second functional area B of the base substrate 1 facing the first conductive layer 2, and the first insulation layer 100 electrically isolates the heat dissipation column 10 in the through hole TGV of the second functional area B from the first conductive layer 2. Alternatively, as shown in FIG. 21b, when the functional hole in the second functional area B is a blind hole BGV, and the opening of the blind hole BGV is located on the side of the base substrate 1 away from the first conductive layer 2, the remaining thickness of the base substrate 1 at the bottom part position of the blind hole BGV may be used to form an electrical isolation between the heat dissipation column 10 and the first conductive layer 2. Regarding the characteristics of the first insulation layer 100, the through hole TGV, and the blind hole BGV, references may be made to the introduction of the above embodiments, and will not be described in detail here.

In addition, as shown in FIG. 20, in an exemplary embodiment, the aperture of the through hole in the first functional area A may be larger than the aperture of the functional hole in the second functional area B, which is beneficial to increasing the inductance value and improving the performance of the filter. The functional hole in the first functional area A has a large aperture, which may adapt to the line width of the first sub-transfer line 221 in the first functional area A. For example, the line width of the first sub-transfer line 221 may be 60 μm, the aperture of the through hole in the first functional area A may be, for example, 50 μm, and the aperture of the functional hole in the second functional area B may be 40 μm, 30 μm, etc.

In an exemplary embodiment, as shown in FIGS. 14 and 16, the first conductive layer 2 may also include a first conductive line 21 and a first transfer line 22. The first transfer line 22 may include a plurality of first sub-transfer lines 221. The first sub-transfer line 221 may be used to form a partial coil structure of the inductor L. The first sub-transfer line 221 is connected between the first conductive column 101 and the second conductive column 102 in adjacent lines. Each conductive column is connected to one of the first sub-transfer lines 221. The first conductive line 21 may extend along the first direction X. The first conductive line 21 may include a first sub-conductive line 211, a second sub-conductive line 212, and a third sub-conductive line 213 that are connected in sequence. The second sub-conductive line 212 forms the first electrode of the capacitor C. The first sub-conductive line 211 is provided corresponding to the first sub-transfer line 221. The first sub-conductive line 211 is connected between the second sub-conductive line 212 and the first sub-transfer line 221 corresponding to the first sub-conductive line 211, thereby connecting the first electrode of the capacitor C to the first terminal of the inductor L. The third sub-conductive line 213 may be connected to the second solder ball 2 of the solder ball layer through a via hole, so that the first terminal of the inductor L and the first electrode of the capacitor C are connected to the second solder ball 2 to form the signal output terminal OUT in FIG. 1.

In an exemplary embodiment, as shown in FIGS. 14 and 17, in the second conductive layer 3, the third conductive line 33 may include a plurality of third sub-conductive parts 331. The third sub-conductive parts 331 are arranged in one-to-one correspondence with the first transfer lines 221. The orthographic projection of the third sub-conductive part 331 on the base substrate 1 may be located on the orthographic projection of the first sub-transfer line 221 on the base substrate 1. The third sub-conductive part 331 may be connected to the corresponding first sub-transfer line 221 through a via hole, which is equivalent to the third conductive line 33 and the second sub-conductive line 212 forming a parallel structure. The second conductive lines 32 may be arranged in one-to-one correspondence with the second sub-conductive lines 212. The orthographic projection of the second conductive line 32 on the base substrate 1 may be located within the orthographic projection of the second sub-conductive line 212 on the base substrate 1, so that the second conductive lines 32 and the second sub-conductive lines 212 are arranged facing each other in one-to-one correspondence to form two facing electrodes of the capacitor C. The second conductive layer 3 may also include a transfer part 34, which is located on the side of the second conductive line 32 away from the third sub-conductive part 331, and is provided corresponding to the third sub-conductive line 213. For example, the orthographic projection of the transfer part 34 on the base substrate may be located within the orthographic projection of the third sub-conductive line 213 on the base substrate. As shown in FIG. 20, the transfer part 34 may connect the third sub-conductive line 213 and the second solder ball 2 of the solder ball layer through respective via holes, thereby forming the signal output terminal OUT in FIG. 1.

In an exemplary embodiment, as shown in FIGS. 18 and 20, the solder ball layer 5 may include a first solder ball 1, a second solder ball 2, and a third solder ball 3. The orthographic projection of the first solder ball 1 on the base substrate 1 may overlap with the orthographic projection of the third sub-conductive part 331 on the base substrate 1. The first solder ball 1 may be connected to the third sub-conductive part 331 of the third conductive layer 4 through a via hole to form the signal input terminal IN in FIG. 1. The orthographic projection of the second solder ball 2 on the base substrate 1 may overlap with the orthographic projection of the third sub-conductive line 213 on the base substrate 1. The second solder ball 2 may be connected to the third sub-conductive line 213 through a via hole, forming the signal output terminal OUT in FIG. 1. The orthographic projection of the third solder ball 3 on the base substrate 1 may overlap with the orthographic projection of the second conductive line 32 on the base substrate 1. The third solder ball 3 may be connected to the second conductive line 32 through a via hole, so that the second electrode of the capacitance C is connected to the ground terminal GND.

In an exemplary embodiment, as shown in FIGS. 14 and 19, the fifth conductive layer 6 is located on the other side of the base substrate 1. The fifth conductive layer 6 may include a plurality of fifth conductive lines 71. The orthographic projection of the fifth conductive line 71 on the base substrate 1 may extend along the first direction X. The fifth conductive line 71 may be connected to the first conductive column 101 and the second conductive column 102 in the same line. Thus, the fifth conductive line 71, the conductive column, the first sub-transfer line 221, and the second conductive line 32 form a spiral winding as a whole. The spiral winding forms a coil of the inductor L. In addition, the line width of the fifth conductive line 71 may be greater than the width of the first conductive column 101 connected thereto and greater than the width of the second conductive column 102 connected thereto.

In an exemplary embodiment, as shown in FIG. 20, the filter may further include a first dielectric layer 210 and a first seed layer 220 stacked on the first conductive layer 2 in sequence. The first dielectric layer 210 is arranged corresponding to the second conductive line 32. The orthographic projection of the first dielectric layer 210 on the base substrate 1 covers the orthographic projection of the second conductive line 32 on the base substrate 1. The first dielectric layer 210 is used to form a dielectric layer of the capacitor C. The material of the first dielectric layer 210 may be SiNx, for example. The plasma enhanced chemical vapor deposition (PECVD) process may be used to deposit a SiNx film of a certain thickness at the position corresponding to the second conductive line 32 on the first conductive layer 2 to obtain the dielectric layer of the capacitor C. The thickness of the SiNx film is adjusted according to the capacitance value of the prepared capacitor C. There is a need to ensure a high flatness of the SiNx film for guaranting the uniformity of the capacitance C. For example, a magnetron sputtering method may be used to deposit a Cu film with a set thickness on the SiNx dielectric layer to obtain the first seed layer 220. The first seed layer 220 serves as the second electrode pad of the capacitor C and the seed layer for generating the second electrode of the capacitor C. The thickness of the Cu film may be greater than or equal to 100 nm, so that the capacitance value of the capacitor C meets the requirements and meets the performance requirements of the filter.

The difference from the filter formed by the two-dimensional inductor L is that in the three-dimensional inductor L, the conductive heat dissipation column 10 in the through hole TGV serves as a partial coil structure of the inductor L. In the area corresponding to the capacitor C, the effect of the functional hole is the same as that of the functional hole in the filter of the two-dimensional inductor L. They are both used as the heat dissipation structure of the filter to improve the heat dissipation performance of the filter. It should be understood that in the filter with the three-dimensional inductor L, the functional hole may have the same structural features as the functional hole in the filter with the two-dimensional inductor L, and the characteristics of the functional hole will not be described again here.

In an exemplary embodiment, the thickness of the fifth conductive layer 6 may be greater than the thickness of the first conductive layer 2. The thickness of the fifth conductive layer 6 may be 1.5 to 3 times the thickness of the first conductive layer 2, and for example, may be 1.5 times, 2 times, 2.5 times, 3 times etc. The thickness of the first conductive layer 2 may be, for example, 3 μm or more. The thickness of the fifth conductive layer 6 may be 5 μm or more, for example. Because the fifth conductive layer 6 is used to form the coil structure of the inductor L, by increasing the thickness of the fifth conductive layer 6, the inductance value of the formed inductor L can be increased, and the loss of the inductor L can be reduced, thereby improving the overall filtering effect of the formed filter.

The present disclosure further provides a method for manufacturing a filter, which may be used to form the filter shown in FIGS. 2 and 14. As shown in FIGS. 22 to 28, it is a process flow chart of the method for manufacturing a filter according to an exemplary embodiment of the present disclosure. The manufacturing method includes the following steps.
S10: providing a base substrate 1.

As shown in FIG. 22, the base substrate 1 may be a glass base substrate 1 or a silicon base substrate 1. The thickness is 0.25 mm to 0.3 mm. For example, the thickness of the glass substrate may be 0.25 mm, 0.27 mm, 0.3 mm, etc.
S20: forming at least one functional hole on the base substrate 1.

As shown in FIG. 23a, the aperture of the functional hole may be 50 μm to 80 μm. For example, the aperture of the functional hole may be 50 μm, 60 μm, 70 μm, or 80 μm. In an exemplary embodiment, a laser drilling or laser-induced etching process may be used to form the functional hole. Due to the thermal effect of laser drilling, the inner wall of the functional hole has a large roughness, which will affect the sputtering of film layers within the functional hole and weaken the bonding force between the film layer in the functional hole and the wall of the functional hole, being not conducive to the preparation of a highly dense adhesion layer and a second seed layer in the hole. The laser-induced etching method may include: using a laser to irradiate the base substrate 1 at a preset position to modify the molecular bonds at the preset position; and then using an etching liquid to etch the base substrate 1 at the preset position to form a through hole TGV, and/or using an etching process to etch the base substrate 1 at the preset position according to a preset aspect ratio to form a blind hole BGV as shown in FIG. 23b, where the blind hole BGV has a preset thickness from the bottom part thereof to the other surface of the base substrate 1. The etching speed of the etching liquid at the preset position of the base substrate 1 is greater than the etching speed at other positions. The etching liquid may be a mixed solution of hydrofluoric acid and nitric acid, a mixed solution of sodium hydroxide and citric acid, etc. The etching liquid may be used to etch functional holes from both sides toward the middle position of the glass substrate. Accordingly, the opening area of the functional hole may gradually decrease from the two openings to the middle position. The wet etching process helps to enable the sidewall of the functional hole to be smoother, thereby facilitating the subsequent bonding of the adhesion layer and the second seed layer with the sidewall of the functional hole. The aspect ratio of the functional hole may be 1.5 to 3. For example, the aspect ratio may be 1.5, 2.0, 2.5, 3.0, etc. For example, the base substrate 1 with a thickness of 0.3 mm may be etched with an aspect ratio of 5:1 to form a blind hole BGV. The distance between the bottom part of the blind hole BGV and the other side of the base substrate 1 is 50 μm. That is, there is a remaining thickness of 50 μm at the bottom part of the blind hole BGV.

In an exemplary embodiment, as shown in FIG. 23a, the opening areas of the functional hole at various positions in the thickness direction of the base substrate 1 may be the same. In addition, the base substrate 1 may also be formed through a wet etching process. For example, a laser may be used to irradiate the base substrate 1 at a preset position to modify the molecular bonds at the preset position of the base substrate 1. The etching speed at the preset position of the base substrate 1 will be greater than the etching speed at other positions of the base substrate 1. Then, the etching liquid is used to etch the base substrate 1 at the preset position to form the functional hole. In an exemplary embodiment, the etching liquid may be used to etch the functional hole from one side to the other side of the glass substrate. Accordingly, as shown in FIG. 23b, the opening area of the functional hole gradually decreases from one opening to the other opening. In another exemplary embodiment, the etching liquid may also be used to etch the functional hole from both sides toward the middle position of the base substrate 1. As shown in FIG. 23c, the opening area of the functional hole may gradually decrease from the two openings to the middle position. It should be understood that the blind hole BGV may be as shown in FIGS. 23d to 23f, and have the same cross-sectional structural features as those shown in FIGS. 23a to 23c.

In an exemplary embodiment, when it is necessary to form a three-dimensional inductor L, the base substrate 1 includes a first functional area A and a second functional area B. The first functional area A forms the inductor L, and the second functional area B forms the capacitor C. Because the heat dissipation column 10 in the first functional area A is used to form a partial coil structure of the inductor L, in the first functional area A, the functional hole needs to be set as a through hole TGV, while in the second functional area B, the functional hole may be a blind hole BGV or a through hole TGV. For example, the formed functional hole may be as shown in FIG. 23g, with the first functional area A and the second functional area B being provided with through hole TGVs. Alternatively, as shown in FIG. 23h, the first functional area A is provided with a through hole TGV, while the second functional area B is provided with a blind hole BGV, and the opening of the blind hole BGV is facing downward (that is, the opening is located on the side of the base substrate 1 away from the first conductive layer 2 to be formed). Alternatively, as shown in FIG. 23i, the first functional hole is a through hole TGV, the second functional hole is a blind hole BGV, and the opening of the blind hole BGV faces upward. That is, the opening of the blind hole BGV is located on the side of the base substrate 1 close to the first conductive layer 2 to be formed. It can be understood that the functional holes in the first functional area A and the second functional area B may have the structures shown in FIG. 23b and/or FIG. 23c.
S30: forming the heat dissipation column 10 in the functional hole.

The thermal conductivity of the heat dissipation column 10 is greater than the thermal conductivity of the base substrate 1. Generally, metal conductive materials have high thermal conductivity. Therefore, in the present disclosure, metal conductive materials may be used to form the heat dissipation column 10, which is conductive column. It is noted that other materials with high thermal conductivity may also be used to form the heat dissipation column 10, and the present disclosure is not limited thereto.

As shown in FIGS. 24a to 24i, the first material may be sputtered in the sidewall of the functional hole to form an adhesion layer. The first seed material may be sputtered on the adhesion layer to form a second seed layer. The heat dissipation material with a preset thickness is sputtered to form the heat dissipation column 10. For example, the first material may be Ti, and the first seed material may be copper. For example, a Ti adhesion layer is first formed on the inner wall of the functional hole through a sputtering process. Then, a copper seed layer of a certain thickness is formed on the Ti adhesion layer. After that, the functional hole is filled by a double-side Cu electroplating process in a butterfly-shaped way to form the copper heat dissipation column 10. The thickness of the adhesion layer may be 5 nm to 30 nm. For example, the thickness of the adhesion layer may be 5 nm, 10 nm, 15 nm, 25 nm, 30 nm, etc. The thickness of the second seed layer may be 30 nm to 80 nm. For example, the thickness of the second seed layer may be 30 nm, 50 nm, 70 nm, 80 nm, etc. In other embodiments, the heat dissipation column 1011 may also be drilled, so that the heat dissipation column 10 is formed as a hollow heat dissipation column 10. The cavity of the hollow heat dissipation column 10 may also be filled with materials such as resin. The thermal expansion coefficient of the material filled in the cavity may be between the thermal expansion coefficient of the heat dissipation column 10 and the thermal expansion coefficient of the base substrate 1. It should be understood that there may be other ways to form the heat dissipation column 10 in the functional hole. For example, the heat dissipation column 10 may be formed in the functional hole by filling a conductive material, a copper-core solder ball, etc.

It can be understood that the formed heat dissipation column 10 may have the same cross-sectional shape as the functional hole, which will not be described in detail here.

It can be understood that FIGS. 24a to 24f are schematic structural diagrams of the heat dissipation column of the two-dimensional inductor L, and FIGS. 24g to 24i are schematic structural diagrams of the heat dissipation column of the three-dimensional inductor L, which will not be described in detail here.
S40: forming the first conductive layer 2 on a side of the base substrate 1. An additive method may be used to deposit a first conductive material with a preset thickness on a side of the first conductive layer 2 to form a first conductive material layer. Then, a patterning process is used to form the first conductive material layer into the first conductive layer 2. After that, the first conductive layer 2 is planarized. As shown in FIG. 25a, the thickness of the first conductive material may be greater than or equal to 3 μm. The first conductive line 21 is formed on the first conductive layer 2 through a patterning process. A partial structure of the first conductive line 21 is used to form the first electrode (lower surface electrode) of the capacitor C. A partial structure forms the first transfer line 22. The first transfer line 22 connects the first terminal of the inductor L and the first electrode of the capacitor C. By performing a planarization process on the first conductive material layer, the flatness of the first conductive line 21 can be improved, and the uniformity of the capacitance C can be improved. It can be understood that when forming the three-dimensional inductor L, a plurality of first sub-transfer lines 221 may be formed in the first functional area A, and the first sub-transfer line 221 forms a partial coil structure of the three-dimensional inductor L.

The first conductive layer 2 is insulated from at least some of the heat dissipation columns 10, so that the heat dissipation column 10 serves as the heat dissipation structure of the filter. In an exemplary embodiment, before forming the first conductive layer 2, the heat dissipation column 10 and the first conductive layer 2 may also be electrically isolated according to the type of functional holes. For example, when the heat dissipation column 10 has a structure as shown in FIGS. 24a to 24c, a first insulation material may be deposited on the entire surface of the base substrate 1 to form a first insulation layer 100. Thus, the heat dissipation column 10 and the first conductive layer 2 are electrically isolated by the first insulation layer 100, so that the introduced heat dissipation column 10 will not affect the performance of the filter while improving the heat dissipation performance of the filter. Alternatively, when the functional hole has a blind hole structure as shown in FIGS. 25d to 25f, there is no need to form an additional insulation layer, and the insulation material left between the other side of the base substrate 1 and the bottom part 101 of the blind hole BGV may be used to electrically isolate the heat dissipation column 10 from the first conductive layer 2. It can be understood that when the inductor L is a three-dimensional inductor L, the functional hole in the first functional area A is a through hole TGV, and the functional hole in the second functional area B may have a structure as shown in FIGS. 25d to 23f. Specifically, when the functional hole in the second functional area B is a through hole TGV as shown in FIG. 25d, or a blind hole structure as shown in FIG. 24i, a first insulation material may be deposited on the side of the base substrate 1 facing the first conductive layer 2 to form a first insulation layer 100 covering the second functional area B. Thus, electrical isolation is formed between the first conductive layer 2 and the heat dissipation column 10 by the first insulation layer 100. Alternatively, when the functional hole in the second functional area B has the structure as shown in FIG. 24h, electrical isolation is achieved between the heat dissipation column 10 and the first conductive layer 2 by the insulation material left between the bottom part of the blind hole BGV and the other side of the base substrate 1.

It can be understood that when electrically isolating the heat dissipation column 10 and the first conductive layer 2 by the first insulation layer 100, a first conductive material of a preset thickness may be deposited on the first insulation layer 100 to form the first conductive material layer, and then a patterning process is performed on the material layer of the first conductive layer 2 to obtain the first conductive layer 2.

It can be understood that FIGS. 25a to 25c are schematic structural diagrams of the two-dimensional inductor L with the first conductive layer, and FIGS. 25d to 25f are schematic structural diagrams of the three-dimensional inductor L with the first conductive layer. The functional holes may have the structural features of the above embodiments, and the functional structure shown in FIG. 23a is taken as an example only for exemplary illustrations, and will not be described in detail here.
S50: forming the second conductive layer 3 on the side of the first conductive layer 2 away from the base substrate 1. A deposition process may be used to deposit a second insulation material on the side of the first conductive layer 2 away from the base substrate 1 to form a third insulation layer PI1. Then, a patterning process may be used to process the third insulation layer PI1 to form an opening to expose a partial structure of the first conductive layer 2. After that, a sputtering process is used to deposit a first seed material at the opening to form a third seed layer. Finally, an electroplating process is used to electroplate a first conductive material with a preset thickness on the third seed layer to form a second conductive layer 3. The second insulation material may be BL-301 or the like. The third insulation layer PI1 entirely covers the first conductive layer 2. Then, the photolithography process may be used to expose, develop, and post-bake the areas of the capacitor C and the inductor L to form openings on the third insulation layer PI1 for exposing partial structures of the first conductive layer 2 respectively. The first seed material may be copper, for example. The second conductive layer 3 is formed by first sputtering the Cu seed layer and then electroplating thick Cu. Part of the second conductive layer 3 is a trace forming the inductor L, and part of the second conductive layer 3 is the second electrode (upper electrode) of the capacitor C. In order to reduce the loss of the inductor L, the thickness of the second conductive layer 3 may be greater than or equal to 5 μm.

As shown in FIGS. 26a to 26c, the second conductive line 32 and the third conductive line 33 may be formed on the second conductive layer 3 through a patterning process. The second conductive line 32 corresponds to the first conductive line 21. For example, the orthographic projection of the second conductive line 32 on the base substrate 1 is located on the orthographic projection of the first conductive line 21 on the base substrate 1. The second conductive line 32 is used to form the second electrode of the capacitor C. The third conductive line 33 is located on one side of the second conductive line 32 and corresponds to the first transfer line 22. The third conductive line 33 is used to form a partial coil structure of the inductor L.

As shown in FIGS. 26d to 26f, when forming the three-dimensional inductor L, the third conductive line 33 located in the first functional area A includes a plurality of third sub-conductive parts 331. The third sub-conductive parts 331 are arranged in one-to-one correspondence with the first sub-transfer lines 221. The orthographic projection of the third sub-conductive part 331 on the base substrate 1 may be located on the orthographic projection of the first sub-transfer line 221 on the base substrate 1. The third sub-conductive part 331 may be connected to the corresponding first sub-transfer line 221 through a via hole, which is equivalent to the third conductive line 33 and the second sub-conductive line 212 forming a parallel structure. The orthographic projection of the second conductive line 32 on the base substrate 1 may be located within the orthographic projection of the second sub-conductive line 212 on the base substrate 1, so that the second conductive line 32 and the second sub-conductive line 212 are arranged facing each other in one-to-one correspondence, forming the two facing electrodes of the capacitor C. The transfer part 34 may also be formed on the second conductive layer 3. The transfer part 34 is located on the side of the second conductive line 32 away from the third sub-conductive part 331, and is provided corresponding to the third sub-conductive line 213.

As shown in FIGS. 26a to 24f, in an exemplary embodiment, before forming the second conductive layer 3, a plasma enhanced chemical vapor deposition process may also be used to deposit a first insulation material of a preset thickness on the first conductive layer 2, forming the first dielectric layer 210 of the capacitor C. A magnetron sputtering process is used to deposit a first seed material with a preset thickness on the first dielectric layer 210 to form the first seed layer 220. For example, the first insulation material may be SiNx. The thickness of the first dielectric layer 210 may be determined according to the relative dielectric constant of the capacitor C and the capacitance value of the capacitor C. For example, a thick SiNx film of 120 nm with high flatness may be deposited to serve as the dielectric layer of the capacitor C structure to ensure the uniformity of the capacitor C. The first seed material may be copper, for example. A thick Cu film of 100 nm may be deposited on the SiNx dielectric layer by a magnetron sputtering method as the upper electrode pad of the capacitor C and the first seed layer 220 for generating the second electrode of the capacitor C. After the first seed layer 220 is obtained, a deposition process may be used to deposit a second insulation material on the first conductive layer 2 and the first seed layer 220 to form a third insulation layer PI1. A patterning process may be used to process the third insulation layer PI1 to form an opening for exposing part of the first conductive layer 2 and part of the first seed layer 220. A sputtering process is used to deposit the first seed material at the opening to form a third seed layer. An electroplating process is used to electroplate the first conductive material with a preset thickness on the third seed layer to form the second conductive layer 3. For example, the second insulation material may be BL-301, etc. The third insulation layer PI1 entirely covers the second conductive layer 3. A photolithography process is used to expose, develop, and post-bake the areas of the capacitor C and the inductor L. An opening is formed in the third insulation layer PI1 to expose partial structures of the second conductive line 32 and the third conductive line 33 as well as a partial structure of the first connection part.

Similarly, because a partial structure of the second conductive layer 3 is used to form a coil structure of the inductor L, the thickness of the second conductive layer 3 may be greater than or equal to 5 μm to increase the value of the inductor L and reduce the loss of the inductor L.

It should be understood that the structures shown in FIGS. 26a to 26c are only showing differences in structure of the functional holes, and the preparation process after the functional holes are forming may be the same.

As shown in FIGS. 26d to 26f, in the filter structure of the three-dimensional inductor L, after forming the second electrode pad of the capacitor C as a seed layer for generating the second electrode of the capacitor C, the first insulation material may be deposited to form a third insulation layers PI1. The third insulation layer PI1 partially covers the first seed layer 220, so that the first seed layer 220 is retracted within the third insulation layer PI1, and the second electrode is electrically isolated from the first electrode of the capacitor C through the third insulation layer PI1.

When the inductor L is a three-dimensional inductor L, the structure of the second conductive layer 3 formed may be as shown in FIGS. 26d to 26f. It can be understood that the structures shown in FIGS. 26d to 24f are only showing the differences in structure of the formed functional holes, and the preparation process after forming the functional holes may be the same.

In an exemplary embodiment, as shown in FIGS. 27a to 27c, after the second conductive layer 3 is formed, a third conductive layer 4 and a solder ball layer 5 may also be formed on the side of the second conductive layer 3 away from the base substrate 1. For example, a second insulation material may be deposited on the second conductive layer 3 to form a fourth insulation layer PI2. Then, a patterning process is used to process the fourth insulation layer PI2 to form an opening to expose part of the second conductive layer 3 located on the first conductive line 21. After that, a sputtering process is used to sputter the first seed material at the opening and the fourth insulation layer PI2 located on the third conductive line 33 to form a fourth seed layer. Finally, an electroplating process is used to electroplate a first conductive material with a preset thickness on the fourth seed sub-layer to form the third conductive layer 4. In the structure of the two-dimensional inductor L, the fourth conductive line 44 may be formed on the third conductive layer 4 through a patterning process. The fourth conductive line 44 is provided corresponding to the third conductive line 33. The fourth conductive line 44 is used to form a partial coil structure of the inductor L. For the structural features of the third conductive line 33 and the fourth conductive line 44, references may be made to the introduction of the above embodiments, and will not be described again here.

In an exemplary embodiment, as shown in FIGS. 27a to 27c, after forming the third conductive layer 4, a second insulation material may be deposited on the third conductive layer 4 to form a fifth insulation layer PI3. Then, a patterning process is used to form three openings at positions corresponding to the fourth conductive lines 44 on the fifth insulation layer PI3, to respectively expose partial structures of some of the fourth conductive lines 44, a partial structure of the second connection part 42, and a partial structure of the third connection part 43. After that, solder balls are implanted in the three openings to form the signal input terminal IN, the signal output terminal OUT, and the ground terminal of the filter.

In an exemplary embodiment, as shown in FIGS. 27d to 27f, in the structure of the three-dimensional inductor L, after the second conductive layer 3 is formed, a sputtering process may be used to sputter a first seed material in the first functional area A on the side of the base substrate 1 away from the first conductive layer 2 to form a fifth seed layer. Then, a first conductive material with a preset thickness is electroplated on the fifth seed layer using an electroplating process to form the fifth conductive layer 6. After that, a patterning process is used to process the fifth conductive layer 6 to form a plurality of fifth conductive lines 71. The fifth conductive line 71 is used to form a partial coil structure of the inductor L. The fifth conductive line is connected between the first conductive column and the second conductive column in the same line. Then, a third insulation material is deposited on the side of the fifth conductive layer 6 away from the base substrate 1 to form the lower surface insulation layer 80. The third insulation material may be, for example, polyimide or acrylic. After the fifth conductive layer 6 and the lower surface insulation layer 80 are formed, solder balls may be implanted in corresponding openings on the upper surface of the base substrate 1 to form the signal input terminal IN, the signal output terminal OUT, and the ground terminal of the filter.

Other embodiments of the present disclosure will be readily apparent to those skilled in the art from consideration of the specification and practice of the content disclosed herein. The present disclosure is intended to cover any variations, uses, or adaptations of the present disclosure that follow the general principles of the present disclosure and include common common sense or customary technical means in the technical field that are not disclosed in the present disclosure. It is intended that the specification and examples be considered as exemplary only.

1. A filter, comprising an inductor and a capacitor, wherein a first electrode of the capacitor is connected to a first terminal of the inductor, and the filter further comprises:
a base substrate, having at least one functional hole;
at least one heat dissipation column, arranged corresponding to the at least one functional hole, wherein the heat dissipation column is filled in the functional hole corresponding thereto; and
a first conductive layer, located on a side of the base substrate,
wherein the first conductive layer comprises:
a first conductive line, a partial structure of the first conductive line being used to form the first electrode of the capacitor;
a first transfer line, connected to a side of the first conductive line; and
a second conductive layer, located on a side of the first conductive layer away from the base substrate,
wherein the second conductive layer comprises:
a second conductive line, arranged corresponding to the first conductive line, wherein an orthographic projection of the second conductive line on the base substrate is located on an orthographic projection of the first conductive line on the base substrate, and the second conductive line is used to form a second electrode of the capacitor; and
a third conductive line, located on a side of the second conductive line and arranged corresponding to the first transfer line, wherein the third conductive line is connected to the first transfer line through a via hole, and the third conductive line is used to form a partial coil structure of the inductor, wherein
at least some of the at least one heat dissipation column is insulated from the first conductive layer, and a thermal conductivity of the heat dissipation column is greater than a thermal conductivity of the base substrate.

2. The filter according to claim 1, wherein
opening areas of the functional hole at various positions are the same; or
the opening area of the functional hole gradually decreases from one side of the base substrate to the other side of the base substrate; or
the opening area of the functional hole gradually decreases from both sides to a middle position of the base substrate.

3. The filter according to claim 2, wherein
a ratio of a length of the functional hole along a thickness direction of the base substrate to an aperture of the functional hole is greater than or equal to 5 and less than or equal to 7.

4. The filter according to claim 1, wherein
the heat dissipation column is a hollow heat dissipation column, and an extension direction of a cavity of the heat dissipation column is the same as an extension direction of the heat dissipation column.

5. The filter according to claim 1, wherein
the heat dissipation column is a solid heat dissipation column.

6. The filter according to claim 4, wherein
the heat dissipation column is a conductive column.

7. The filter according to claim 6, wherein the filter further comprises:
a first dielectric layer, located between the first conductive layer and the second conductive layer, wherein the first dielectric layer is arranged corresponding to the second conductive line, and an orthographic projection of the first dielectric layer on the base substrate covers an orthographic projection of the second conductive line on the base substrate; and
a first seed layer, located between the first dielectric layer and the second conductive layer, wherein the first seed layer is used as a seed layer for forming the second conductive layer.

8. The filter according to claim 7, wherein the filter further comprises:
a third conductive layer, located on a side of the second conductive layer away from the base substrate, wherein
the third conductive layer comprises a fourth conductive line, arranged corresponding to the third conductive line, and used to form a partial coil structure of the inductor;
the third conductive line and the fourth conductive line are arranged in a bending way, and an orthographic projection of the third conductive line on the base substrate and an orthographic projection of the fourth conductive line on the base substrate enclose a winding area; and
a first end of the third conductive line is connected to a first end of the fourth conductive line through a via hole, a second end of the third conductive line is connected to the first transfer line through a via hole, and an extension direction from the first end to the second end of the third conductive line is the same as an extension direction from the first end to a second end of the fourth conductive line.

9. The filter according to claim 7, wherein
a thickness of the second conductive layer and a thickness of the third conductive layer are both greater than a thickness of the first conductive layer.

10. (canceled)

11. The filter according to claim 8, wherein
the second conductive layer further comprises:
a first connection part, located between the second conductive line and the third conductive line and arranged corresponding to the first conductive line, wherein the first connection part is connected to the first conductive line through a via hole,
the third conductive layer further comprises:
a second connection part, arranged corresponding to the second conductive line, wherein an orthographic projection of the second connection part on the base substrate at least partially overlaps with an orthographic projection of the second conductive line on the base substrate, and the second connection part is connected to the second conductive line through a via hole; and
a third connection part, arranged corresponding to the first connection part, wherein an orthogonal projection of the third connection part on the base substrate at least partially overlaps with an orthogonal projection of the first connection part on the base substrate, and the third connection part is connected to the first connection part through a via hole, and
the filter further comprises:
a solder ball layer, located on a side of the third conductive layer away from the base substrate, wherein the solder ball layer comprises:
a first solder ball, an orthographic projection of the first solder ball on the base substrate overlapping with an orthographic projection of the fourth conductive line on the base substrate, and the first solder ball being connected to an end of the fourth conductive line through a via hole;
a second solder ball, an orthographic projection of the second solder ball on the base substrate overlapping with an orthographic projection of the third connection part on the base substrate, and the second solder ball being connected to the third connection part through a via hole; and
a third solder ball, an orthographic projection of the third solder ball on the base substrate overlapping with an orthographic projection of the second connection part on the base substrate, and the third solder ball being connected to the second connection part through a via hole.

12. The filter according to claim 11, wherein
the functional hole is a blind hole, and an opening of the blind hole is located on a side of the base substrate away from the first conductive layer.

13. The filter according to claim 11, wherein
the functional hole is a through hole, or the functional hole is a blind hole and an opening of the blind hole is located on a side of the base substrate close to the first conductive layer; and
the filter further comprises:
a first insulation layer, covering the base substrate on a side facing the first conductive layer.

14. The filter according to claim 7, wherein
the base substrate comprises a first functional area and a second functional area, wherein an orthographic projection of the first transfer line on the base substrate is located in the first functional area, an orthographic projection of the first conductive line on the base substrate is located in the second functional area, each of the first functional area and the second functional area comprises the functional hole, and the functional hole in the first functional area is a through hole; and
the plurality of heat dissipation columns located in the first functional area comprises a plurality of first conductive columns and a plurality of second conductive columns, wherein the plurality of first conductive columns and the plurality of second conductive columns are arranged at intervals along the same direction respectively, the first conductive column and the second conductive column are arranged side by side, and the first conductive column and the second conductive column are used to form partial coil structures of the inductor,
the filter further comprises:
a fifth conductive layer, located on a side of the base substrate away from the first conductive layer, wherein the through hole is located in an area corresponding to an orthographic projection of the fifth conductive layer on the base substrate, and
the fifth conductive layer comprises:
a plurality of fifth conductive lines, the fifth conductive line being connected between the first conductive column and the second conductive column in the same line, wherein
the first transfer line comprises a plurality of first sub-transfer lines, wherein the first sub-transfer line is used to form a partial coil structure of the inductor, the first sub-transfer line is connected between the first conductive column and the second conductive column in adjacent lines, and each heat dissipation column is connected to one of the first sub-transfer lines.

15. The filter according to claim 14, wherein
the third conductive line comprises a plurality of third sub-conductive parts, the third sub-conductive parts being arranged corresponding to the first sub-transfer lines, and the third sub-conductive part being connected to the first sub-transfer line corresponding thereto through a via hole,
the second conductive layer further comprises:
the first conductive line comprises a first sub-conductive line, a second sub-conductive line, and a third sub-conductive line connected in sequence, the second sub-conductive line being used to form the first electrode of the capacitor, the first sub-conductive line being arranged corresponding to the first sub-transfer line, and the first sub-conductive line being connected between the first sub-conductive line and the first sub-transfer line corresponding to the second sub-conductive line, and
the filter further comprises a solder ball layer, located on a side of the third conductive layer away from the base substrate, wherein
the solder ball layer comprises:
a first solder ball, an orthographic projection of the first solder ball on the base substrate overlapping with an orthographic projection of the third sub-conductive part on the base substrate, and the first solder ball being connected to an end of the third sub-conductive part through a via hole;
a second solder ball, an orthographic projection of the second solder ball on the base substrate overlapping with an orthographic projection of the third sub-conductive line on the base substrate, and the second solder ball being connected to the third sub-conductive line through a via hole; and
a third solder ball, an orthographic projection of the third solder ball on the base substrate overlapping with an orthographic projection of the second conductive line on the base substrate, and the third solder ball being connected to the second conductive line through a via hole.

16. The filter according to claim 14, wherein
an aperture of the functional hole in the first functional area is larger than an aperture of the functional hole in the second functional area.

17. (canceled)

18. The filter according to claim 14, wherein
an orthographic projection of the first sub-transfer line on the base substrate covers orthographic projections on the base substrate of the second conductive line and the first conductive column connected thereto; and
an orthographic projection of the fifth conductive line on the base substrate covers orthographic projections on the base substrate of the second conductive line and the first conductive column connected thereto.

19. The filter according to claim 14, wherein
the functional hole in the second functional area is a blind hole, and an opening of the blind hole is located on a side of the base substrate away from the first conductive layer.

20. The filter according to claim 14, wherein
the functional hole in the second functional area is a through hole, or the functional hole in the second functional area is a blind hole, and an opening of the blind hole is located on a side of the base substrate close to the first conductive layer; and
the filter further comprises:
a first insulation layer, covering the second functional area of the base substrate on a side facing the first conductive layer.

21.-25. (canceled)

26. A method for manufacturing a filter, wherein the filter comprises an inductor and a capacitor, a first electrode of the capacitor is connected to a first terminal of the inductor, and the manufacturing method comprises:
providing a base substrate;
forming at least one functional hole on the base substrate;
forming at least one heat dissipation column in the at least one functional hole;
forming a first conductive layer on a side of the base substrate, wherein the first conductive layer is insulated from at least some of the at least one heat dissipation column, the first conductive layer comprises a first conductive line and a first transfer line, a partial structure of the first conductive line is used to form the first electrode of the capacitor, and the first transfer line is connected to a side of the first conductive line;
forming a second conductive layer on a side of the first conductive layer away from the base substrate, wherein the second conductive layer comprises a second conductive line and a third conductive line, the second conductive line is arranged corresponding to the first conductive line, an orthographic projection of the second conductive line on the base substrate is located on an orthographic projection of the first conductive line on the base substrate, the second conductive line is used to form a second electrode of the capacitor, the third conductive line is located on a side of the second conductive line and arranged corresponding to the first transfer line, the third conductive line is connected to the first transfer line through a via hole, and the third conductive line is used to form a partial coil structure of the inductor.

27.-35. (canceled)

36. An electronic device, comprising a filter, wherein
the filter comprises an inductor and a capacitor, wherein a first electrode of the capacitor is connected to a first terminal of the inductor, and the filter further comprises:
a base substrate, having at least one functional hole;
at least one heat dissipation column, arranged corresponding to the at least one functional hole, wherein the heat dissipation column is filled in the functional hole corresponding thereto; and
a first conductive layer, located on a side of the base substrate,
wherein the first conductive layer comprises:
a first conductive line, a partial structure of the first conductive line being used to form the first electrode of the capacitor;
a first transfer line, connected to a side of the first conductive line; and
a second conductive layer, located on a side of the first conductive layer away from the base substrate,
wherein the second conductive layer comprises:
a second conductive line, arranged corresponding to the first conductive line, wherein an orthographic projection of the second conductive line on the base substrate is located on an orthographic projection of the first conductive line on the base substrate, and the second conductive line is used to form a second electrode of the capacitor; and
a third conductive line, located on a side of the second conductive line and arranged corresponding to the first transfer line, wherein the third conductive line is connected to the first transfer line through a via hole, and the third conductive line is used to form a partial coil structure of the inductor, wherein
at least some of the at least one heat dissipation column is insulated from the first conductive layer, and a thermal conductivity of the heat dissipation column is greater than a thermal conductivity of the base substrate.
